(19) United States
(12) Patent Application Publication
(10) Pub. No.: US 2026/0305153 A1
(43) Pub. Date: Oct. 1, 2026

(54) APPARATUS AND METHODS FOR DISCOVERY, OPTIMIZATION, SELECTION, AND SYNTHESIS OF HIGH-EFFICIENCY TRANSPARENT OPV DONOR-ACCEPTOR PAIRS

(71) Applicant: Mohsen Rezayat, Cincinnati, OH (US)

(72) Inventor: Mohsen Rezayat, Cincinnati, OH (US)

(21) Appl. No.: 19/679,111

(22) Filed: May 15, 2026

Related U.S. Application Data
(63) Continuation-in-part of application No. PCT/US2024/059056, filed on Dec. 6, 2024.
(60) Provisional application No. 63/606,877, filed on Dec. 6, 2023.
(60) Provisional application No. 63/947,747, filed on Dec. 23, 2025.

(51) Int. Cl. H10K 71/70; G01B 9/02; G01B 11/06; H02S 40/36; H02S 40/38; H10K 30/50; H10K 71/40

(52) U.S. Cl. CPC H10K 71/70; G01B 9/02083; G01B 11/0675; H02S 40/36; H02S 40/38; H10K 30/50; H10K 71/40

(57) ABSTRACT

A computer-implemented apparatus and method are disclosed for discovering, optimizing, selecting, and generating synthesis instructions for donor-acceptor molecular pairs for transparent organic photovoltaic (OPV) active layers. Candidate donor and acceptor molecules are preprocessed from molecular graphs or strings, spectral data, and textual data. A candidate reduction module reduces the candidate space using molecular validity, synthetic accessibility, spectral compatibility, compliance, molecular-language-model embedding, diversity selection, uncertainty-based selection, or combinations thereof. A graph neural network generates structure and spectral embeddings, and a large language model generates text embeddings. A fusion module forms multimodal embeddings that are optimized according to objectives including increased luminance utilization efficiency and maintained or increased average visible transmittance. Selected donor-acceptor pairs are used to generate synthesis instructions, with optional uncertainty estimation, validation, compliance filtering, explainability, provenance tracking, and closed-loop experimental feedback.

### CROSS-REFERENCE TO RELATED APPLICATIONS

The present application claims priority to U.S. Provisional Patent Application Ser. No. 63/947,747, filed Dec. 23, 2025, and is a continuation-in-part of PCT International Patent Application No. PCT/US2024/059056, filed Dec. 6, 2024, which claims priority to U.S. Provisional Patent Application Ser. No. 63/606,877, filed Dec. 6, 2023, the disclosures of which are expressly incorporated herein by reference.

### BACKGROUND AND SUMMARY OF THE INVENTION

The present disclosure relates to printed three-dimensional (“3D”) solar panels that have improved efficiency and transparency.

Food and energy crises have swept the globe in recent decades. Sustainable techniques such as agrivoltaics that efficiently utilize farmland are the key to resolving this problem. However, conventional opaque solar panels completely block sun light and create large areas of shade. Conversely, semitransparent solar panels installed as a canopy above crops would enable farmers to efficiently use land for both agriculture and solar photovoltaic energy generation.

With reference to FIGS. 1A and 1B of the drawings, a conventional solar farm 10 is shown as including a plurality of solar panels 12a, 12b, 12c to receive electromagnetic radiation 15 from the sun 14. A plurality of support or posts 16a, 16b, 16c support the solar panels 12a, 12b, 12c for pivoting movement relative thereto. A panel angle controller 18a, 18b, 18c may drive the panels in motion between the position shown in FIG. 1A and the position shown FIG. 1B. In FIG. 1A normal operating conditions are shown. In FIG. 1B, the solar panels 12 may be rotated during conditions of strong sunlight. The controllers 18a, 18b, 18c may be in communication with a climate sensor box 20 and a wireless sensing and panel control system 22. As the panels are rotated between positions in FIG. 1A and FIG. 1B, shade 23 may extend to cover vegetation 24a, 24b and/or individuals 26 positioned adjacent to the support post 16a, 16b, 16c. Crops 24c are illustratively outside of the shade area 23 of the solar panels 12a, 12b, 12c.

As illustrated in FIGS. 2A and 2B, the wavelengths of electromagnetic radiation 15 (sunlight) span from short-wavelength ultraviolet (UV) light 32 (100 nm to 400 nm), visible light 34 (400 nm to 700 nm), short-wave near infrared (SNIR) light 36 (700 nm to 1100 nm) to long-wave near infrared (LNIR) light 38 (1100 nm to 2500 nm). Whereas solar cells can utilize basically any spectral region for energy production, crops need visible light 34 (400 nm to 700 nm) for healthy growth (e.g., photosynthesis). Semi-transparency of solar panels in visible spectrum, not 100% transparency in visible spectrum, is enough for most crops. By wisely designing the absorption spectrum of organic solar cells that are semitransparent in visible spectrum (see FIGS. 2A and 2B), one can efficiently utilize land for both energy production and agriculture. The opportunity here is that, currently, there is a trade-off between efficiency and transparency in commercial organic photovoltaics (OPVs) and the present disclosure minimizes this compromise.

To be more precise, by controlling the absorption spectrum of multiple cells stacked on top of each other and ensuring that each cell can function in different ranges within spectral regions, one can design OPV cells that are complementary and not competing with one another for generation of electricity while at the same time configuring components in an innovative way to ensure transmittance of visible light to the crops below. Such unique configuration could involve use of antireflective layers, adjusting dielectric thicknesses, adjusting donor/acceptor ratio in active layer, etc. In FIGS. 2A and 2B, it can be seen that photons from the sun have many wavelengths and that we can design OPV cells that absorb these wavelengths at a relatively narrow range while allowing most of the wavelengths in the visible range to pass through and thus, with additional configuration, provide transparent cells. Note that the term transparent as used herein encompasses an average visible transparency of a straight through beam of 45% or more whereas semitransparent is 10% to 45%. In other words, whenever “transmitting light between 400 nm and 700 nm” is stated, it means that overall, it is desired to get 45% of the visible light to pass through the totality of the 3D OPV panel and reach the crops or vegetation.

More particularly, light absorbance of two representative polymers are shown in the spectral graphs of FIG. 2B, with visible light representative by plot 42, absorbance of the first polymer represented by plot 44, and absorbance of the second polymer represented by plot 46.

Although there is still the need for research in order to discover more limited-range wavelength materials that can attain UV and IR absorption and visible light transmission, we have enough processing techniques and existing materials to achieve our objectives. For instance, through microcavity structure, we can selectively transmit and reflect light at specific wavelengths by adjusting the dielectric thicknesses. Furthermore, thousands of materials are currently known from the literature that can be used to identify the appropriate chemical structure of controlled-range cells. And if needed, through AI-guided sample selection, we can autonomously discover and synthesize in laboratory new polymer materials that are complementary in their range and thus can be stacked on top of each other as complete cells and connected in parallel to increase the efficiency of the overall 3D OPV panel.

As previously mentioned, a primary goal for this invention is improving food production in energy-producing farms with economic benefits to farmers, as well as enhancing sustainability. The results from this invention have the potential to expand the general market for OPV panels and thus greatly contribute to the commercial success of third-generation solar cells and possibly revolutionize the solar energy industry.

Combining commercial agriculture and solar energy on the same area of land (i.e., agrivoltaics) is an important area of research in our increasingly resource-deprived and populated world. Farmers across the world generally agree that there is a need to align renewable energy goals with agricultural concerns through an effective and economical agrivoltaics system. Energy-producing greenhouses, as a special type of agrivoltaics system, have been studied by multiple researchers in recent years. It is generally agreed by those in the art that OPV modules are highly suitable for agrivoltaics, but efficiency and longevity issues must be resolved for commercial viability.

For the more general case of canopy over farmland or building-integrated photovoltaics, semi-transparent OPVs have a variety of merits such as low weight, low environmental impact, and (potentially) short energy payback time. With improvements in transparency and efficiency, there is a significant opportunity for high-yield and environmental-friendly agriculture through integration with OPVs. Finally, due to the unique band structure of organic materials, OPVs are able to selectively absorb light with a desired wavelength. This characteristic can be exploited to create highly efficient photovoltaics and photosynthetic systems to address food and energy needs if efficiency and durability challenges of OPVs could be resolved.

As further detailed herein, proper light transmittance is important to the success of OPVs for agriculture and other applications. In addition to agrivoltaics, transparent OPVs can be integrated onto windowpanes in buildings and automobiles, and used for retrofitting existing traditional silicon solar arrays on rooftops and solar farms to increase their electric production. Note that these traditional panels mainly absorb visible light to generate electricity and that is why they are opaque. Since transparent 3D OPV panels of the present disclosure are extremely light, such retrofitting does not add much weight.

Three generations of solar cells and materials used to create them are highlighted in FIG. 3. Third-generation solar cells (e.g., OPVs) are understood to have the highest “theoretical” efficiency as well as the lowest manufacturing cost. This is despite the fact that, currently, 89% of the global solar cell market is made up of first-generation (e.g., silicon) solar cells mainly because OPVs are far from reaching this stated theoretical potential. One of the main goals of the solar panel design of the present disclosure is to take the first steps in changing the current trend of using inorganic and opaque silicon solar panels by making OPVs commercially viable and a good match for agrivoltaics. Conventional silicon solar cells (i.e., first-generation solar cells) contain materials that are mined and must be manufactured in airtight vacuum sealed chambers and dust free rooms, which significantly drives up the cost of manufacturing. The second-generation solar cells typically use CdTe (Cadmium Telluride) as the photovoltaic material along with a conductive layer of material such as aluminum. Disadvantages of using this type of solar cells include presence of cadmium, which is a toxic metal that also needs to be mined, and the fact that the final product is extremely heavy, since thick glass is used on both sides for encapsulation.

Third-generation solar cells are typically made of carbon-based organic polymer materials made in laboratories, and can be manufactured at atmospheric pressure and ambient temperature, using potentially low-cost commercial ink jet or roll-to-roll printers 50 (see FIG. 4); thus, they could become much cheaper to make once they reach mass production. More particularly, a substrate 52 may extend between rotatable rolls 53 and have layers 54 printed thereon.

Although a primary advantage of using organic solar cells is their potential low cost of production (when mass produced), their true value lies in the spectral tunability, thin outline, low weight, flexibility, freeform design, and sustainability. Solar inks used to make the OPV cells are typically composed of a polymer/fullerene or polymer/non-fullerene blends. The ink may consist of a photoactive layer made up of positively charged (i.e., p-type) polymer (i.e., donor) and a negatively charged (i.e., n-type) fullerene or non-fullerene (i.e., acceptor) that are combined with a cathode and an anode suspended on a substrate (FIG. 5). Since the system can be applied in layered coatings, it is possible to use existing ink jet printer technologies to print working solar cells. They can be printed straight onto paper-thin, flexible plastic, as well as onto steel and thin glass, and can be made semi-transparent for agrivoltaics projects. The consistency of organic printed solar technology is better than inorganic silicon, and thus, they work well in cloudy conditions and are recyclable and non-toxic. Note that organic waste is biodegradable whereas inorganic waste is significantly more difficult to decompose. However, most critical for an agrivoltaics project is the optical properties of organic photoactive material, which can be tuned via chemical and structural modifications. In fact, OPVs could be positioned as the most naturally suited solar technology for agrivoltaics if they are engineered to focus the absorption of light in the ultraviolet (UV) and infrared (IR) regions, allowing semi-transparency in the visible (so-called photosynthesis) range. Addressing challenges with the selection of appropriate materials for transmittance, correct design and processing techniques, and better durability and efficiency will ultimately determine the commercial viability of OPVs.

As is known, the solar radiation arriving at the Earth is distributed across different wavelengths. The radiation power of each wavelength received by unit area is known as the Spectral Irradiance. Agricultural plants utilize specialized pigments to intercept and capture photon energy of the sun for growth. Within the broad light spectrum, the Photosynthetically Active Radiation (PAR) activates the plant pigments, transforming light energy into chemical energy for production of carbon molecules (such as sugar) within 400-700 nm visible spectrum range. Therefore, OPV materials that absorb wavelength below 400 nm (i.e., UV) and above 700 nm (i.e., infrared), and transmit everything in between, are desired. As for durability, OPVs need only to retain performance for 10 years to become commercially competitive, although a 20-year lifetime is possible if delamination due to wind could be reduced. Three stages of OPV life is known as an initial period of steep degradation (i.e., burn-in period) followed by a period of relatively constant degradation lasting for most of the solar cells' usable lifetime, and ending with rapid and complete degradation that results in device failure.

With further reference to FIG. 5, conventional commercial OPV cells 60 (also known as Organic Solar Cells or OSCs) are made of 3 main parts:
1. Organic Photovoltaic Material: Donor-acceptor materials (i.e., cooperating donor material 62 and acceptor material 64) are carbon-based and can be synthesized in a laboratory unlike inorganic materials that require mining/processing.
2. Conductive Materials for Electrodes: Transparent conductive oxide material is used as an anode 66 and on the other side a cathode 68 is typically a metal, like silver.
3. Protective Encapsulation Layer: Glass, plastics, or composites prolong the lifespan of cells by protecting against moisture, oxygen, and other environmental factors.

OPV panels have a better temperature coefficient than silicon-based panels, meaning that their efficiency is less affected by high temperatures and that they will lose a smaller portion of their performance when it gets too hot. Although third-generation panels have a shorter lifespan as compared to first- and second-generation panels, they have the fastest payback time because of the potential for lower material and implementation costs. Use of advanced substrate materials, such as Dyneema Composite Fabric, has led to significant improvements in the longevity of these panels, but more needs to be done in this regard.

To summarize, current top-of-the-line commercial OPV cells have an efficiency of about 7% and a life span of about 10 to 20 years, whereas traditional silicon solar PV cells are closer to 25% efficient and typically have a life expectancy of 20 to 30 years. So, to reach competitive commercial viability, research is needed for the third-generation panels to increase their efficiency and durability, and to better control their transmissivity characteristics. As part of the validation process, we will test our innovatively designed 3D OPV panels to illustrate that they address all these developmental needs, in addition to introducing several other unique features in the context of effective agrivoltaics, and thus improve the commercial viability of organic panels.

There is a need for improved printed solar panels that are more efficient and more durable than currently available solar panel options.

There is also a need to align renewable energy goals with agricultural concerns through an effective and economically unique agrivoltaics system design.

The present disclosure relates to light-weight, three-dimensional (“3D”) solar panels that increase the efficiency as well as the durability of printed solar panels. In one embodiment, the solar panels are comprised of multi-layer ultra-thin printed solar technology.

Embodiment 1: According to an illustrative embodiment of the present disclosure, a solar panel array includes a support, a first panel operatively coupled to the support, a second panel operatively coupled to the support in space relation to the first panel, and a third panel operatively coupled to the support in space relation to the second panel. The first panel includes a first substrate, and a first photovoltaic layer supported by the first substrate. The first photovoltaic layer absorbs ultraviolet light and is transparent to visible light. The second panel includes a second substrate, and a second photovoltaic layer supported by the second substrate. The seconds photovoltaic layer absorbs short-wave near infrared (SNIR) light and transparent to visible light. The third panel includes a substrate, and third photovoltaic layer supported by the third substrate. The third photovoltaic layer absorbs long-wave near infrared (LNIR) light and transparent to visible light.

Embodiment 2: The solar panel array of embodiment 1, further including:
a fourth photovoltaic layer absorbing ultraviolet light and transparent to visible light;
wherein the first photovoltaic layer is supported on an upper surface of the first substrate;
wherein the second photovoltaic layer is between the lower surface of the first substrate and the upper surface of the second substrate;
wherein the third photovoltaic layer is between the lower surface of the second substrate and the upper surface of the third substrate; and
wherein the fourth photovoltaic layer is supported on a lower surface of one of the first substrate, the second substrate and the third substrate.

Embodiment 3: The solar panel array of embodiment 2, wherein the fourth photovoltaic layer is supported on a lower surface of the third substrate and facing outward.

Embodiment 4: The solar panel array of embodiment 1, wherein:
the first panel is supported above the second panel, the first panel defining an upper panel; and
the second panel is supported above the third panel, the third panel defining a lower panel.

Embodiment 5: The solar panel array of embodiment 1, wherein the support includes a frame and a plurality of fasteners coupling together the first panel, the second panel and the third panel.

Embodiment 6: The solar panel array of embodiment 5, further including a support post, and an adjustable bracket operably coupling the frame to the support post above vegetation in a solar farm.

Embodiment 7: The solar panel array of embodiment 5, further including a coupler securing the frame to a building roof.

Embodiment 8: The solar panel array of embodiment 1, wherein:
the first substrate of the first panel is formed of a translucent polymer, and the first photovoltaic layer is a first donor:acceptor material composition printed on a surface of the first panel;
the second substrate of the second panel is formed of a translucent polymer, and the second photovoltaic layer is a second donor:acceptor material composition printed on a surface of the second panel; and
the third substrate of the third panel is formed of a translucent polymer, and the third photovoltaic layer is a third donor:acceptor material composition printed on a surface of the third panel.

Embodiment 9: The solar panel array of embodiment 8, wherein the first donor:acceptor material composition is a diketopyrrolopyrrole (DPP) based polymer for absorbing light having wavelengths between 100 nanometers and 400 nanometers, the second donor:acceptor material composition is a thiophene-based polymer for absorbing light having wavelengths between 700 nanometers and 1100 nanometers, and the third donor:acceptor material composition is a PBDTTT derivative for absorbing light having wavelengths between 1100 nanometers and 2500 nanometers.

Embodiment 10: The solar panel array of embodiment 9, wherein the first donor:acceptor material composition is P3HT-DPP:Y6, the second donor:acceptor material composition is PBDB-T:Y6, and the third donor:acceptor material composition is PTB7:Y6.

Embodiment 11: The solar panel array of embodiment 8, wherein:
each of the first photovoltaic layer, the second photovoltaic layer and the third photovoltaic layer have a thickness of less than 0.1 inches; and
the combined thickness of the first panel the second panel and the third panel, including their substrates, have a thickness of about 1 inch.

Embodiment 12: The solar panel array of embodiment 1, wherein each of the first substrate, the second substrate and the third substrate includes a twin-wall planar sheet including an upper layer, a lower layer and a heat sink positioned intermediate the upper layer and the lower layer.

Embodiment 13: The solar panel array of embodiment 12, wherein the heat sink includes a plurality of parallel hollow channels including opposing open ends to permit air flow therethrough.

Embodiment 14: The solar panel array of embodiment 1, wherein:
each of the first photovoltaic layer, the second photovoltaic layer and the third photovoltaic layer includes at least a first cell and a second cell;
the first cell and the second cell electrically coupled in series with each other; and
the first photovoltaic layer, the second photovoltaic layer and the third photovoltaic layer electrically coupled in parallel with each other.

Embodiment 15: The solar panel array of embodiment 1, wherein:
the first photovoltaic layer includes a first organic material and transmits light having wavelengths between 400 nanometers and 700 nanometers;
the second photovoltaic layer includes a second organic material and transmits light having wavelengths between 400 nanometers and 700 nanometers; and
the third photovoltaic layer includes a third organic material and transmits light having wavelengths between 400 nanometers and 700 nanometers.

Embodiment 16: The solar panel array of embodiment 15, wherein:
the first organic material of the first photovoltaic layer absorbs light having wavelengths between 100 nanometers and 400 nanometers;
the second organic material of the second photovoltaic layer absorbs light having wavelengths between 700 nanometers and 1100 nanometers; and
the third organic material of the third photovoltaic layer absorbs light having wavelengths between 1100 nanometers and 2500 nanometers.

Embodiment 17: The solar panel array of embodiment 16, wherein the first organic material composition is a diketopyrrolopyrrole (DPP) based polymer, the second organic material composition is a thiophene-based polymer, and the third organic material composition is a PBDTTT derivative.

Embodiment 18: The solar panel array of embodiment 17, wherein the first organic material composition is P3HT-DPP:Y6, the second organic material composition is PBDB-T:Y6, and the third organic material composition is PTB7:Y6.

Embodiment 19: The solar panel array of embodiment 16, further including a light utilization efficiency (LUE) of at least 3.4%, preferably at least 4.5%, and an average visible transmittance (AVT) of at least 34%, preferably at least 45%.

Embodiment 20: The solar panel array of embodiment 8, wherein at least one of the first donor:acceptor material composition, the second donor:acceptor material composition, and the third donor:acceptor material composition is determined from a predefined database of donors: acceptors by a processor executing machine readable instructions of an artificial intelligence program stored in memory in order to provide a desired absorption wavelength range.

Embodiment 21: The solar panel array of embodiment 1, further including a fourth panel including a fourth substrate, and a fourth photovoltaic layer supported by the fourth substrate, the fourth photovoltaic layer's donor:acceptor material having a peak absorption within a wavelength range of one of ultraviolet light, short-wave near infrared (SNIR) light, and long-wave near infrared (LNIR) light.

Embodiment 22: According to another illustrative embodiment of the present disclosure, a solar power generating system includes a first solar panel having a first substrate, and a first photovoltaic layer supported by the first substrate. The first photovoltaic layer absorbs at least one of ultraviolet light, short-wave near infrared (SNIR) light, and long-wave near infrared (LNIR) light, and is transparent to visible light. The first substrate includes an upper layer, and lower layer and a heat sink position intermediate the upper layer and the lower layer. The heat sink includes a plurality of parallel hollow channels including opposing open ends to permit air flow therethrough.

Embodiment 23: The solar power generating system of embodiment 22, further including:
a maximum power point tracking (MPPT) device electrically coupled to the first panel, the second panel and the third panel, a battery bank in electrical communication with the maximum power point tracking device the maximum power point tracking device optimizing power output from each of the first photovoltaic layer, the second photovoltaic layer and the third photovoltaic layer and accounts for voltage and current differences between the first photovoltaic layer, the second photovoltaic layer and the third photovoltaic layer;
a battery bank in electrical communication with the maximum power point tracking device; and
a load in electrical communication with the maximum power point tracking device.

Embodiment 24: The solar power generating system of embodiment 22, further including:
a second solar panel operably coupled to the support in spaced relation to the first solar panel, the second solar panel including a second substrate, and a second photovoltaic layer supported by the second substrate, the second photovoltaic layer absorbing short-wave near infrared (SNIR) light and transparent to visible light; and
a third solar panel operably coupled to the support in spaced relation to the second solar panel, the third solar panel including a substrate, and a third photovoltaic layer supported by the third substrate, the third photovoltaic layer absorbing long-wave near infrared (LNIR) light and transparent to visible light.

Embodiment 25: The solar power generating system of embodiment 24, further including a frame and a plurality of fasteners coupling together the first panel, the second panel and the third panel.

Embodiment 26: The solar power generating system of embodiment 24, wherein:
each of the first photovoltaic layer, the second photovoltaic layer and the third photovoltaic layer includes at least a first cell and a second cell;
the first cell and the second cell electrically coupled in series with each other; and the first photovoltaic layer, the second photovoltaic layer and the third photovoltaic layer electrically coupled in parallel with each other.

Embodiment 27: The solar power generating system of embodiment 24, wherein:
the first photovoltaic layer transmits light having wavelengths between 400 nanometers and 700 nanometers;
the second photovoltaic layer transmits light having wavelengths between 400 nanometers and 700 nanometers; and
the third photovoltaic layer transmits light having wavelengths between 400 nanometers and 700 nanometers.

Embodiment 28: The solar power generating system of embodiment 27, wherein:
the first photovoltaic layer absorbs light having wavelengths between 100 nanometers and 400 nanometers;
the second photovoltaic layer absorbs light having wavelengths between 700 nanometers and 1100 nanometers; and
the third photovoltaic layer absorbs light having wavelengths between 1100 nanometers and 2500 nanometers.

Embodiment 29: The solar power generating system of embodiment 28, wherein the first photovoltaic layer is a diketopyrrolopyrrole (DPP) based polymer, the second photovoltaic layer is a thiophene-based polymer, and the third photovoltaic layer is a PBDTTT derivative.

Embodiment 30: The solar power generating system of embodiment 29, wherein the first photovoltaic layer is P3HT-DPP:Y6, the second photovoltaic layer is PBDB-T:Y6, and the third photovoltaic layer is PTB7:Y6.

Embodiment 31: The solar power generating system of embodiment 28, further including a light utilization efficiency (LUE) of at least 4.5%, and an average visible transmittance (AVT) of at least 45%.

Embodiment 32: The solar panel array of embodiment 28, wherein at least one of the first photovoltaic layer, the second photovoltaic layer, and the third photovoltaic layer is selected from a predefined database of donor:acceptor materials by a processor executing machine readable instructions of an artificial intelligence program stored in memory in order to provide a desired absorption wavelength.

Embodiment 33: According to a further illustrative embodiment of the present disclosure, a method for manufacturing solar panel includes the steps of providing a first substrate, providing a conveyor to move the first substrate, heating the first substrate, and applying a first liquid photovoltaic material to the first substrate to a define a first photovoltaic layer. The method further includes the steps of using an interferometer to measure thickness of the first photovoltaic layer, using a camera to detect point defects in the first photovoltaic, and providing a controller in electrical communication with the conveyor, the interferometer and the camera, the controller including a processor and a memory having software with machine readable instructions.

Embodiment 34: The method of embodiment 33, wherein the first substrate includes a translucent twin-wall polymer.

Embodiment 35: The method of embodiment 34, wherein the first substrate includes an upper layer, a lower layer and a heat sink positioned intermediate the upper layer and the lower layer.

Embodiment 36: The method of embodiment 35, wherein the heat sink includes a plurality of parallel hollow channels including opposing open ends to permit air flow therethrough.

Embodiment 37: The method of embodiment 33, wherein the first liquid photovoltaic material is one of a first polymer based material for transmitting light having wavelengths between 400 nanometers and 700 nanometers and for absorbing light having wavelengths between 100 nanometers and 400 nanometers, a second polymer based material for transmitting light having wavelengths between 400 nanometers and 700 nanometers and for absorbing light having wavelengths between 700 nanometers and 1100 nanometers, and a third polymer based material for transmitting light having wavelengths between 400 nanometers and 700 nanometers and for absorbing light having wavelengths between 1100 nanometers and 2500 nanometers.

Embodiment 38: The method of embodiment 37, wherein the first polymer based material includes a diketopyrrolopyrrole (DPP) based polymer, the second polymer based material includes a thiophene-based polymer, and the third polymer based material includes a PBDTTT derivative.

Embodiment 39: The method of embodiment 33, wherein the applying step includes providing a syringe and a pump to supply the first liquid photovoltaic material to the syringe.

Embodiment 40: The method of embodiment 33, further including a light positioned on an opposite side of the first substrate, the camera configured to detect light passing through point defects in the first photovoltaic layer.

Embodiment 41: The method of embodiment 33, further including an adjustable blade for controlling the thickness of the first photovoltaic layer.

Embodiment 42: The method of embodiment 41, wherein the controller controls a speed of the conveyor and the position of the adjustable blade.

Embodiment 43: The method of embodiment 33, further including the steps of:
providing a second substrate;
moving the second substrate via the conveyor;
heating the second substrate;
applying a second liquid photovoltaic material to the second substrate to define a second photovoltaic layer;
providing a third substrate;
moving the third substrate via the conveyor;
heating the third substrate;
applying a third liquid photovoltaic material to the third substrate to define a third photovoltaic layer;
wherein the first photovoltaic layer absorbs ultraviolet light and is transparent to visible light;
wherein the second photovoltaic layer absorbs short-wave near infrared (SNIR) light and is transparent to visible light; and
wherein the third photovoltaic layer absorbs long-wave near infrared (LNIR) light and is transparent to visible light.

Embodiment 44: The method of embodiment 43, wherein:
the first photovoltaic layer transmits light having wavelengths between 400 nanometers and 700 nanometers;
the second photovoltaic layer transmits light having wavelengths between 400 nanometers and 700 nanometers; and
the third photovoltaic layer transmits light having wavelengths between 400 nanometers and 700 nanometers.

Embodiment 45: The method of embodiment 44, wherein:
the first photovoltaic layer absorbs light having wavelengths between 100 nanometers and 400 nanometers;
the second photovoltaic layer absorbs light having wavelengths between 700 nanometers and 1100 nanometers; and
the third photovoltaic layer absorbs light having wavelengths between 1100 nanometers and 2500 nanometers.

Embodiment 46: The method of embodiment 45, wherein at least one of the first photovoltaic layer, the second photovoltaic layer, and the third photovoltaic layer is selected from a predefined database of donor:acceptor materials by the processor executing the machine readable instructions of an artificial intelligence program stored in the memory in order to provide a desired absorption wavelength.

Embodiment 47: According to another illustrative embodiment of the present disclosure, a method of synthesizing an organic photovoltaic cell includes the steps of training a computer system on known organic molecules that act as donors and as acceptors of energy in the electromagnetic spectrum to create a trained computer system or model, prompting the trained computer system to design organic molecules that act as acceptors and organic molecules that act as donors simultaneously optimize current production from energy and ultraviolet portion of the electromagnetic spectrum, and minimize absorption of energy for light in the visible portion of the electromagnetic spectrum. The method further includes the steps of using the organic acceptors and the organic donors designed in the first step, to further train the computer model to create a robust trained computer system. The method also includes the steps of instructing the robust trained computer system to design and expanded set of organic acceptors and expanded set of organic donors, wherein one or more of the organic molecules in the expanded set of acceptors and wherein one or more of the organic molecules in the expanded set of organic donors simultaneously produce from energy in the ultraviolet portion of the electromagnetic spectrum, and minimize absorption of energy of light in the visible portion of the electromagnetic spectrum. The method further includes the step of requiring the robust trained computer system to identify pairs of donors and acceptors which produce a current from the ultraviolet portion of the electromagnetic spectrum while minimizing the absorbance of energy from the visible portion of the electromagnetic spectrum.

Embodiment 48: The method according to embodiment 47, wherein:
the ultraviolet portion of the electromagnetic spectrum has wavelengths between 100 nanometers and 400 nanometers; and
the light in the visible portion has wavelengths between 400 nanometers and 700 nanometers.

Embodiment 49: The method according to embodiment 47, wherein:
the short-wave near infrared (SNIR) portion of the electromagnetic spectrum has wavelengths between 700 nanometers and 1100 nanometers; and
the light in the visible portion has wavelengths between 400 nanometers and 700 nanometers.

Embodiment 50: The method according to embodiment 47, wherein the long-wave infrared (IR) portion of the electromagnetic spectrum has wavelengths between 1100 nanometers and 2500 nanometers; and the light in the visible portion has wavelengths between 400 nanometers and 700 nanometers.

Embodiment 51: The methods according to embodiments 47 to 50, wherein the computer system uses machine learning.

Embodiment 52: The method according to embodiment 51, wherein the robust trained computer system includes a large language model (LLM).

Embodiment 53: The method according to embodiments 47 to 52, further include an extraction step, wherein the extraction step extracts data from spectra to form extracted data for use in training a computer system.

Embodiment 54: The method according to embodiment 53, wherein the extraction step is performed by a hierarchical graph neural network (Hierarchical GNN) program or a graph neural network (GNN) program.

Embodiment 55: The method according to embodiment 52, wherein the training step uses Large Language Model embeddings and GNN embedding or H-GNN embedding to train a multimodal model, wherein the multimodal models integrates GNN embedding or H-GNN embeddings and LLM embeddings.

Embodiment 56: According to a further illustrative embodiment of the present disclosure, an apparatus for synthesizing organic photovoltaic cells includes a preprocessing data module, wherein the preprocessing data module produces training data, and a model training module for training a machine wherein the training module uses multimodal training data to train a Generative Artificial Intelligence model to identify donor:acceptor material as the active layer in an organic photovoltaic cell. The desired active layer primarily absorbs electromagnetic energy in at least one or more ranges selected from the group consisting of: 100 nm to 400 nm, 700 nm to 1100 nm, and 1100 nm to 2500 nm. An organic acceptor/organic donor optimizing module receives the donor:acceptor material identified by the model training module.

Embodiment 57: The apparatus according to embodiment 56, wherein the prepossessing data module, processes one or more forms of data selected from the group consisting of: molecular strings, spectral graphs, and text, to produce processed data suitable for training one or more Generative Artificial Intelligence Models.

Embodiment 58: The apparatus according to embodiment 57, wherein the preprocessed data module employs a Graph Neural Network (GNN).

Embodiment 59: The apparatus according to embodiment 57, wherein the preprocessed data module employs a Hierarchical Graph Neural Network (Hierarchical GNN).

Embodiment 60: The apparatus according to embodiments 58 to 59, wherein the Graph Neural Network or the Hierarchical Graph Neural Network provides structural information and relationship understanding from chemical structure and or spectral-characteristic graphical data for use in training a machine.

Embodiment 61: The apparatus according to embodiments 56 to 60, wherein the Generative Artificial Intelligence is a Large Language Model.

Embodiment 62: The apparatus according to embodiments 56 to 61, wherein the Generative Artificial Intelligence possesses a sematic multimodal understanding and uses the semantic multimodal understanding to identify the desirable organic acceptor-organic donors.

Embodiment 63: The apparatus, according to embodiments 56 to 62, wherein the preprocessing data module further includes a data abstraction module for abstracting an interface between the data module and the model training module.

Embodiment 64: The apparatus according to embodiments 56 to 63, wherein the organic acceptor organic donor optimizer module optimizes acceptor-donor pairs to increase Light Utilization Efficiency (LUE).

Embodiment 65: The apparatus according to embodiments 56 to 64, wherein the organic acceptor organic donor optimizer module optimizes acceptor-donor pairs to increase Light Utilization Efficiency (LUE) to values that are greater than or equal to 4.5%.

Embodiment 66: The apparatus according to embodiments 56 to 65, wherein the organic acceptor organic donor optimizer module optimizes acceptor-donor pairs to decrease average visible transmittance (AVT).

Embodiment 67: The apparatus according to embodiment 66, wherein the AVT is greater than 45%.

Embodiment 68: The apparatus according to embodiments 56 to 67, further including a synthesis module which receives output from the optimizer module and interfaces with a synthesis module.

Embodiment 69: The apparatus according to embodiment 68, wherein the synthesis module is a 3-D printer.

Embodiment 70: The apparatus according to embodiments 68 to 69, wherein the synthesis module a is a large language model that outputs instructions for the synthesis of organic acceptor and organic donor molecules identified by the optimizer module.

Embodiment 71: According to another illustrative embodiment of the present disclosure, a method for synthesizing organic photovoltaic cells includes processing data using a preprocessing data module, wherein the preprocessing data module produces training data, and training a machine using a model training module, for training a machine wherein the training module uses multimodal training data to train a Generative Artificial Intelligence model to identify donor:acceptor material as the active layer in an organic photovoltaic cell. The desired active layer primarily absorbs electromagnetic energy in at least one or more ranges selected from the group consisting of: 100 nm to 400 nm, 700 nm to 1100 nm, and 1100 nm to 2500 nm. The method further includes optimizing one or more organic acceptors organic donors using an optimizing module, executed on a trained machine.

Embodiment 72: The method according to embodiment 71, wherein the prepossessing data module, processes one or more forms of data selected from the group consisting of: molecular strings, spectral graphs, and text, to produce processed data suitable for training one or more Generative Artificial Intelligence Models.

Embodiment 73: The method according to embodiment 72, wherein the preprocessed data module employs a Graph Neural Network (GNN).

Embodiment 74: The method according to embodiment 72, wherein the preprocessed data module employs a Hierarchical Graph Neural Network (Hierarchical GNN).

Embodiment 75: The methods according to embodiments 73 and 74, wherein the Graph Neural Network or the Hierarchical Graph Neural Network provides structural information and relationship understanding from chemical structure and or spectral-characteristic graphical data for use in training a machine.

Embodiment 76: The methods according to embodiments 71 to 75, wherein the Generative Artificial Intelligence is a Large Language Model.

Embodiment 77: The methods according to embodiments 71 to 76, wherein the Generative Artificial Intelligence possesses a sematic multimodal understanding and uses the semantic multimodal understanding to identify the desirable organic acceptor-organic donors.

Embodiment 78: The methods, according to embodiments 71 to 77, wherein the preprocessing data module further includes a data abstraction module for abstracting an interface between the data module and the model training module.

Embodiment 79: The methods according to embodiments 71 to 78, wherein the organic acceptor organic donor optimizer module optimizes acceptor-donor pairs to increase Light Utilization Efficiency (LUE).

Embodiment 80: The methods according to embodiments 71 to 78, wherein the organic acceptor organic donor optimizer module optimizes acceptor-donor pairs to increase Light Utilization Efficiency (LUE) to values that are greater than or equal to 4.5%.

Embodiment 81: The methods according to embodiments 71 to 80, wherein the organic acceptor organic donor optimizer module optimizes acceptor-donor pairs to decrease average visible transmittance (AVT).

Embodiment 82: The methods according to embodiment 81, wherein the AVT is greater than 45%.

Embodiment 83: The methods according to embodiments 71 to 82, further including a synthesis module which receives output from the optimizer module and interfaces with a synthesis module.

Embodiment 84: The methods according to embodiment 83, wherein the synthesis module is a 3-D printer.

Embodiment 85: The methods according to embodiments 83 to 84, wherein the synthesis module a is a large language model that outputs instructions for the synthesis of organic acceptor and organic donor molecules identified by the optimizer module.

This disclosure further relates to systems and methods for computational materials discovery in Organic Photovoltaics (OPVs) using multimodal machine learning, including apparatus modules for preprocessing, embedding, optimization, selection, and synthesis instruction generation. More specifically, it concerns a computer-implemented system that uses graph neural networks (GNNs), large language models (LLMs), multimodal embeddings, and multi-objective optimization to (i) identify, (ii) score, and (iii) generate synthesis procedures for donor-acceptor molecular pairs suitable for use as active layers in transparent OPV films that transmit visible light while harvesting ultraviolet (UV) and near-infrared (NIR) light. Among other uses, such OPV solar devices can be utilized as a canopy over crops or on greenhouses in agrivoltaics projects, integrated into windows and facades of buildings, placed on the body of electric vehicles (EVs), or embedded in portable devices.

Certain illustrative embodiments relate to transparent OPV devices, stacked OPV panel architectures, and computer-implemented systems for identifying suitable transparent OPV materials. In some illustrative embodiments, multimodal machine-learning pipelines integrate molecular, spectral, and textual data to support GNN/LLM embeddings, multimodal fusion, multi-objective optimization of LUE and AVT, candidate selection, and synthesis-instruction generation. Additional illustrative computer-implemented systems and data-processing architectures are described in the detailed description below.

Transparent or semitransparent OPVs require a co-optimized trade-off: high energy harvesting predominantly outside the visible spectrum while transmitting visible light at defined AVT levels. Traditional approaches lack a unified representation of molecular structure, spectra, and text-based operational knowledge, limiting their ability to output candidates with practical, fabrication-aligned synthesis procedures for transparency while preserving efficiency of OPVs.

Transparent OPV devices used in applications such as agrivoltaics, smart buildings and EVs, and portable electronics must satisfy two goals that usually oppose each other.
1. They must pass a significant portion of visible light, for example, greater than 45% AVT through the panel, to maintain human visual comfort, plant growth, and daylighting.
2. They must still convert non-visible portions of the spectrum, for example, ultraviolet (UV), short-wave near-infrared (SNIR), and/or long-wave near-infrared (LNIR) bands, to electrical energy at meaningful efficiency. One metric for this is LUE, which captures how effectively spectral bands outside the visible window are turned into usable electrical output. For example, for transparent OPVs, LUE of higher than 4.5% is considered optimal.

Classical materials discovery methods in OPVs depend on human experts screening candidate donor/acceptor molecules, often using computational chemistry and simulation technologies, followed by fabrication and measurement of thin films using the selected materials. This process may be slow, biased by known chemistries, and not well suited to joint optimization considering two or more targets (e.g. “maximize LUE while maintaining or increasing AVT”).

One alternative aspect of the disclosure is to use Artificial Intelligence (AI) methodologies. Recent AI-based work in materials science tends to fall into one of two buckets:
1. graph-based molecular property prediction (i.e., Graph Neural Networks or GNNs), or
2. text-driven models that mine prior art, publications, and lab notes (i.e., Large Language Models or LLMs).

One approach that appears to be missing, or at least not fully developed is a single pipeline that:
fuses structured chemical/spectral representations with unstructured text,
optimizes for the explicit OPV objectives (AVT, spectral selectivity, LUE),
selects synthetically viable donor-acceptor pairs from a design space, and
emits actionable synthesis instructions that can be handed directly to a chemist or automated synthesis station.

Some aspects of the instant invention seek to develop and further develop this approach to designing and synthesizing raw materials.

One goal is to discover, rank, and propose the synthesis of donor-acceptor molecular pairs that can be used as active layers in an OPV stack that:
transmits a target fraction of visible light (e.g. above 45% AVT through the active region);
absorbs and converts energy primarily outside the visible spectrum; for example, in ultraviolet (100-400 nm) and in near-infrared (700-2500 nm) as shown in FIG. 2A; and
increases total luminance utilization efficiency (LUE) above 4.5% compared to known materials.

A “donor-acceptor pair” in this apparatus means one electron donor molecule and one electron acceptor molecule selected for a bulk heterojunction active layer (see FIG. 5) of a transparent OPV or multi-layered transparent 3D OPV (see FIG. 9). As used herein, “donor material” and “acceptor material” may include small molecules, polymers, oligomers, molecular fragments, fullerene acceptors, non-fullerene acceptors, donor:acceptor blends, active-layer formulations, or combinations thereof. As used herein, a “donor-acceptor material composition” may include one or more donor materials and one or more acceptor materials selected for use together in an OPV active layer, including a bulk heterojunction active layer, multilayer active structure, printed thin-film composition, or other organic photovoltaic material system.

The illustrative system described here automates discovery and synthesis planning of OPV donor-acceptor pairs using multimodal AI by:
1. Receiving multiple modalities of data for a library of candidate donor and acceptor molecules: molecular graphs or strings, optical absorption/emission spectra, and textual descriptions from literature, disclosures, and lab notebooks.
2. Using a graph neural network (GNN or hierarchical GNN) to generate embeddings that represent molecular structure and predicted optoelectronic behavior.
3. Using a large language model (LLM) to generate embeddings that represent textual knowledge such as reported synthesis conditions, film morphology notes, stability issues, solvent compatibility, toxicity concerns, etc.
4. Fusing these embeddings into a single multimodal representation for each candidate or donor-acceptor pair.
5. Applying an optimizer that scores candidates against multi-objective targets, for example:
   maximize luminance utilization efficiency (LUE),
   maintain or increase average visible transmittance (AVT),
   bias absorption into UV and/or NIR instead of visible ranges.
6. Selecting one or more donor-acceptor pairs predicted to satisfy the targets.
7. Generating synthesis instructions, using the LLM conditioned on the optimized multimodal representation, including precursor identification, solvent systems, temperature ranges, anneal conditions, and thin-film deposition steps.

In some illustrative embodiments, the system further includes a staged candidate down-selection process configured to reduce computational cost before applying one or more graph neural network, hierarchical graph neural network, geometric graph neural network, or physics-aware scoring modules. The staged candidate down-selection process may include one or more low-cost screening stages, including rule-based chemical validity filters, synthetic accessibility filters, toxicity or compliance filters, spectral-window filters, molecular-language-model embeddings, transformer-based molecular-string embeddings, similarity clustering, diversity selection, and approximate property predictors. In such embodiments, a molecular language model may generate preliminary embeddings or scores from tokenized molecular representations, molecular descriptors, molecular fragments, OPV-specific text, synthesis-related text, spectral descriptions, or combinations thereof, and only a subset of candidate donor molecules, acceptor molecules, or donor-acceptor pairs satisfying one or more preliminary criteria are passed to the GNN-based embedding, fusion, or optimization modules.

The staged candidate down-selection process may preserve not only top-scoring candidates but also candidates selected for chemical diversity, structural novelty, high uncertainty, or predicted outlier performance. In this manner, the apparatus reduces computational cost and improves scalability while mitigating premature convergence toward known molecular families. In some illustrative embodiments, the candidate reduction module may be implemented as a separate module, as an integrated portion of the preprocessing module, as an integrated portion of a routing module or staged evaluation engine, or as a learned or rule-based filtering stage executed before graph neural network processing. The candidate reduction module may operate once before embedding, iteratively during optimization, or both.

In some illustrative embodiments:
The system predicts uncertainty and model confidence, and uses that information to prioritize which candidates should be fabricated first.
The system incorporates experimental feedback (measured spectra, measured AVT and LUE, film defects, etc.) back into the training loop, thereby improving later predictions and synthesis instructions. This creates a closed optimization loop.

In another illustrative aspect, the disclosure provides an apparatus (or system) that may include:
a preprocessing module,
a candidate reduction module configured to reduce a candidate space before graph neural network processing,
an embedding module containing (i) a GNN for molecular/spectral data and (ii) an LLM for textual data,
a multimodal fusion module,
an optimization module that evaluates LUE and AVT objectives and produces ranked donor-acceptor pairs, and
a synthesis interface module that outputs stepwise instructions for fabricating those pairs.

In another illustrative aspect, the disclosure provides a computer-implemented apparatus or system for identifying transparent OPV donor-acceptor material compositions. The apparatus may include a preprocessing module, a candidate reduction module configured to reduce a candidate space before graph neural network processing, an embedding module containing a graph neural network for molecular or spectral data and a large language model for textual data, a multimodal fusion module, an optimization module that evaluates LUE and AVT objectives, a selector that outputs ranked donor-acceptor material compositions, and a synthesis interface that outputs stepwise fabrication instructions.

In some illustrative embodiments, the apparatus may further include uncertainty estimation, compliance filtering, provenance tracking, validation, and feedback-loop functionality. These components may support scalable candidate reduction, multimodal embedding, multi-objective optimization, synthesis planning, experimental validation, and active-learning updates for transparent OPV material discovery.

Additional features and advantages of the present invention will become apparent to those skilled in the art upon consideration of the following detailed description of illustrative embodiments exemplifying the best mode of carrying out the invention as presently perceived.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1A is a side elevational view of a conventional agrivoltaics farm, showing the solar panels in a first position under normal sunlight conditions;

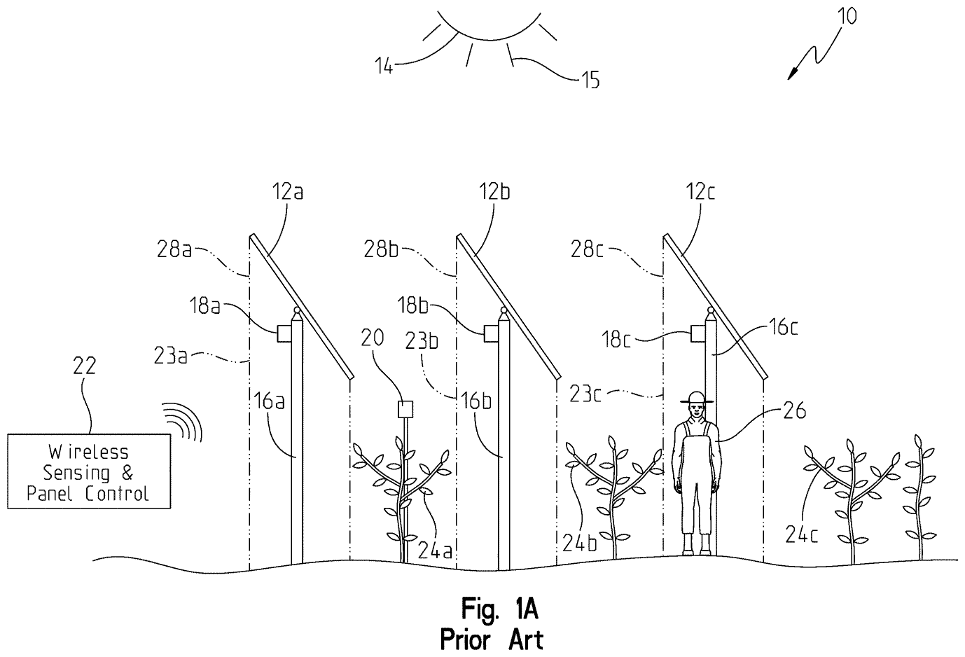

FIG. 1B is a side elevational view of the conventional agrivoltaics farm of FIG. 1A, showing the solar panels in a second position under strong sunlight conditions;

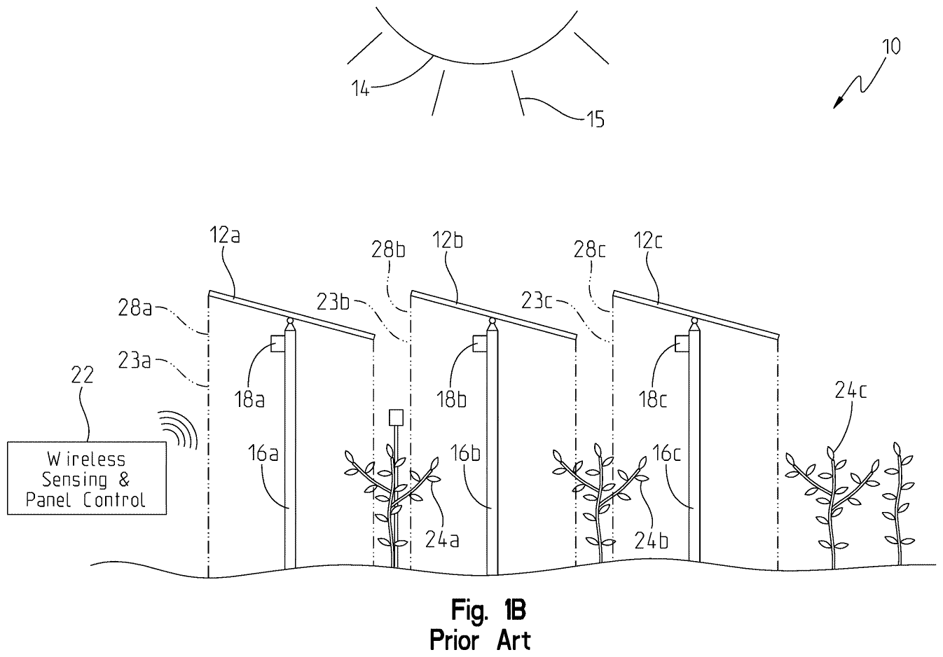

FIG. 2A is a spectral graph of electromagnetic radiation from the sun;

FIG. 2B is a spectral graph showing electromagnetic absorption wavelengths of two illustrative polymers;

FIG. 3 is a table showing three generations of photo voltaic (PV) cells;

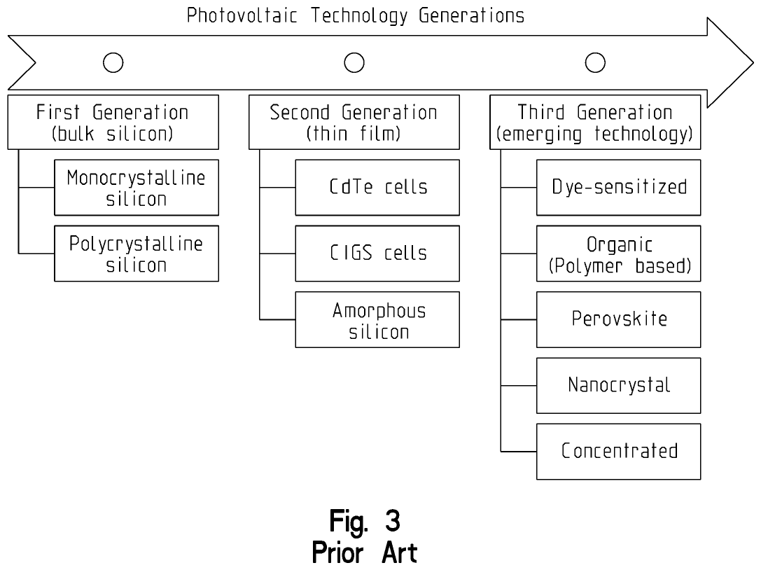

FIG. 4 shows a conventional polymer-based printed solar cell;

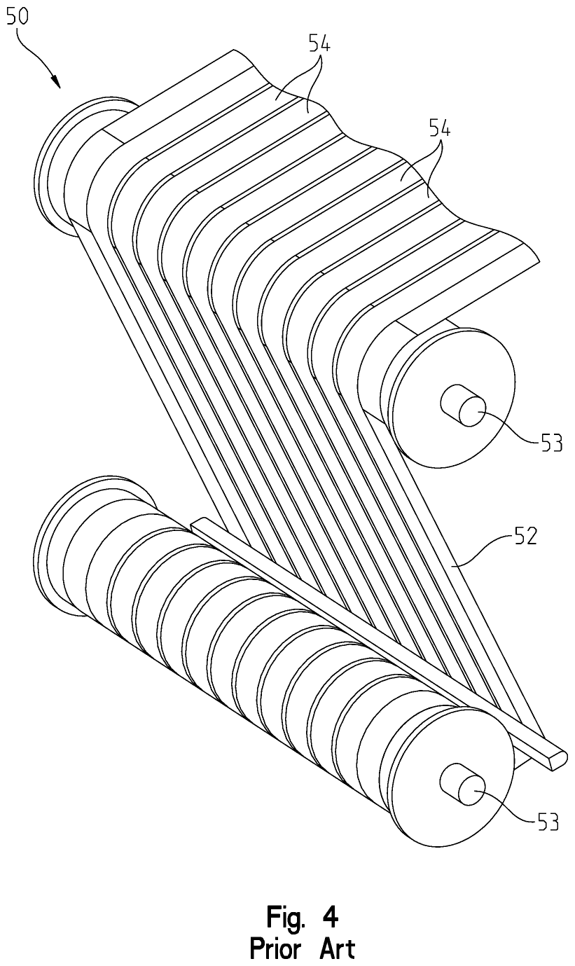

FIG. 5 is a diagrammatic view of a conventional organic solar cell;

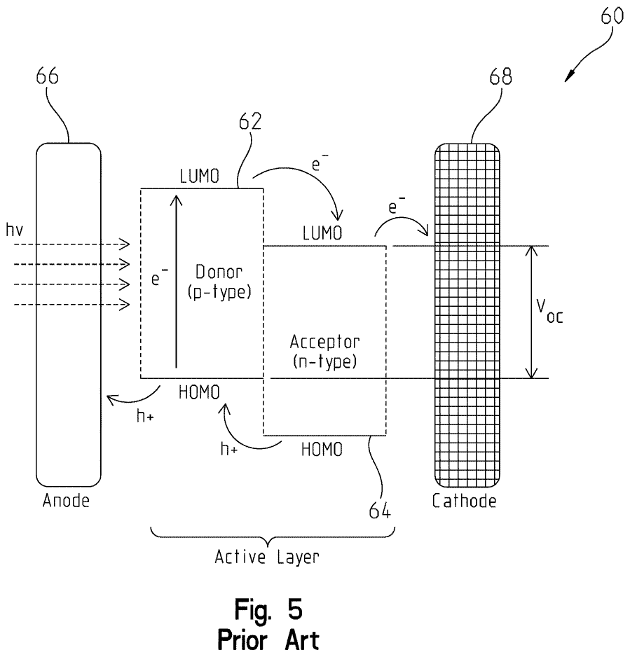

FIG. 6 is a front perspective view of an illustrative solar panel system of the present disclosure;

FIG. 7 is a rear perspective view of the voltaic solar panel system of FIG. 6;

FIG. 8 is a top perspective view of an illustrative solar panel array;

FIG. 9 is an exploded perspective view of a solar panel array with multiple layers;

FIG. 10 is a detailed perspective view of the solar panel array of FIG. 8;

FIG. 11 is a partial cross-sectional view of the solar panel array of FIG. 8;

FIG. 12 is a diagrammatic view including installation apparatus of the solar panel array of FIG. 8;

FIG. 13 is a spectral graph showing absorbance curves for the layers of the solar panel array of FIG. 8;

FIG. 14A shows solar-tracking mounting systems for testing all three generations of panels before mounting on poles;

FIG. 14B shows a solar canopy using wooden poles for testing all three generations of panels for agrivoltaics projects;

FIG. 14C shows a greenhouse equipped with the first-generation solar panels;

FIG. 14D shows a greenhouse equipped with the third-generation low-efficiency solar panels;

FIG. 15 is a diagrammatic view of active layers of the solar panel array of FIG. 8;

FIG. 16 is a schematic view showing electrical connectors;

FIG. 17 is a diagrammatic view of an illustrative printed organic solar cell;

FIG. 18 is a diagrammatic view of an illustrative manufacturing methods;

FIG. 19 is an illustration showing one computer implemented system that can be used to identify and/or or develop materials suitable of use in the manufacture of organic photovoltaics for example cells useful in agrivoltaics applications;

FIG. 20 is a block diagram of an illustrative computer system that can be used to identify and/or to develop materials suitable of use in the manufacture of organic photovoltaics for example, for example cell useful in agrivoltaics applications;

FIG. 21 is a block diagram of an apparatus 400 illustrating AI apparatus modules including preprocessing module 410, candidate reduction module 415, embedding module 420, fusion module 430, optimization module 440, uncertainty estimator 450, compliance filter 460, selector 470, synthesis interface 480, and outputs 490 with provenance 495;

FIG. 22 is a block diagram of a preprocessing pipeline 500 including molecular strings or graphs 511, spectral data 512, textual corpora 513, preprocessing+candidate reduction module 520, GNN/H-GNN embeddings 530, LLM embeddings 540, and fusion 550;

FIG. 23 is a block diagram of a multimodal fusion stack 600 producing multimodal embedding 630 from GNN token sequence 601 and LLM token sequence 602 via projections 603, 604, attention 610, and pooling 620;

FIG. 24 is a graph illustrating an optimization scene 700 including candidates 701, Pareto-front candidates 710, final selection 720, AVT axis 731, and LUE axis 732; and

FIG. 25 is a block diagram illustrating a synthesis interface 800 including recipe fields 801-803 and 811-813, constraints 820, provenance 830, and outputs associated with a selected donor-acceptor material composition.

For the purposes of promoting and understanding the principles of the present disclosure, reference will now be made to the embodiments illustrated in the drawings, which are described herein. The embodiments disclosed herein are not intended to be exhaustive or to limit the invention to the precise form disclosed. Rather, the embodiments are chosen and described so that others skilled in the art may utilize their teachings. Therefore, no limitation of the scope of the claimed invention is thereby intended. The present invention includes any alterations and further modifications of the illustrated devices and described methods and further applications of principles in the invention which would normally occur to one skilled in the art to which the invention relates.

### DETAILED DESCRIPTION OF THE DRAWINGS

The embodiments hereinafter disclosed are not intended to be exhaustive or limit the invention to the precise forms disclosed in the following description. Rather the embodiments are chosen and described so that others skilled in the art may utilize its teachings.

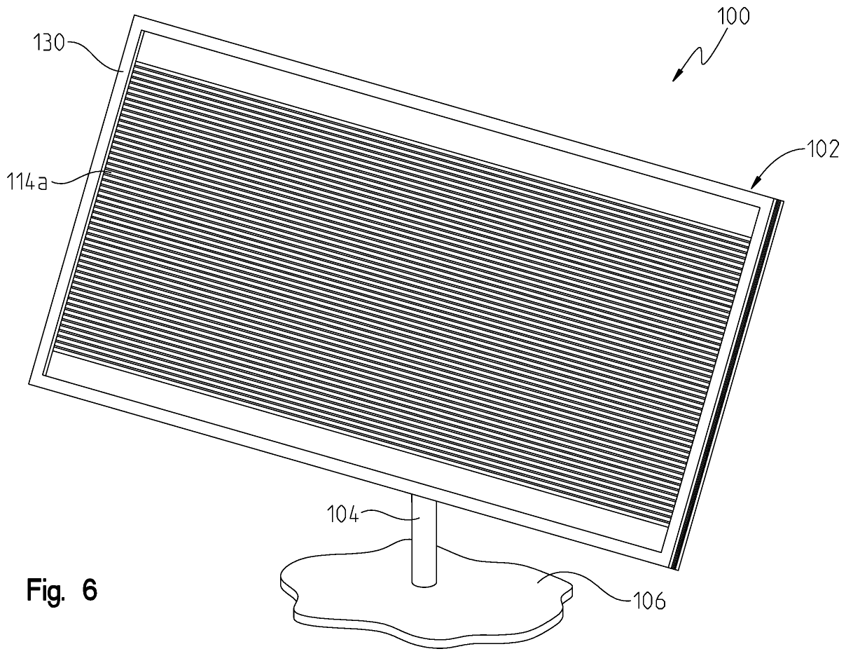

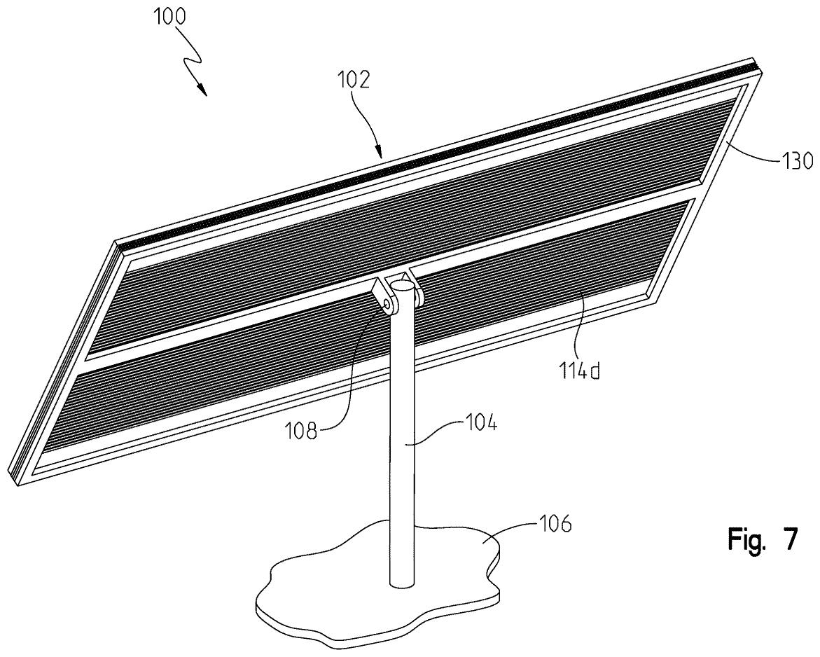

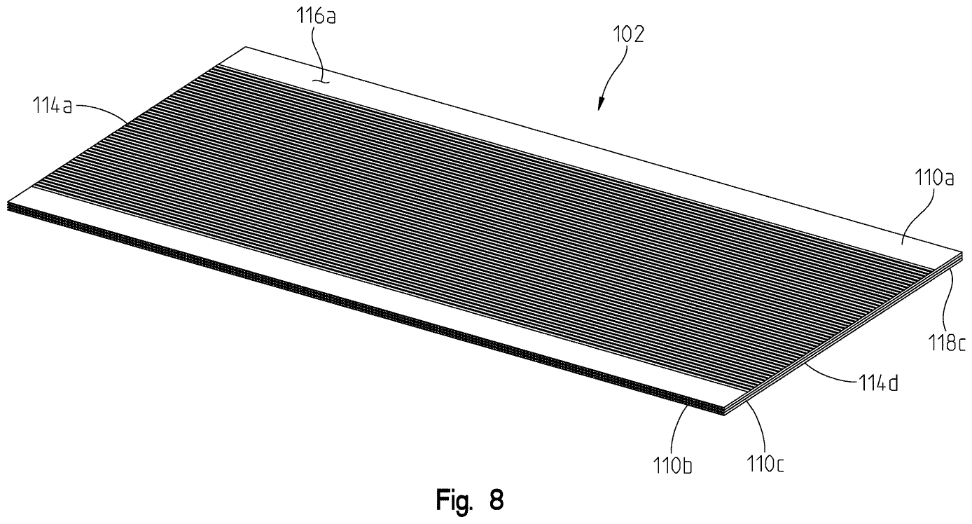

With reference to FIGS. 6-9, a solar power generating system 100 is shown as including an illustrative solar panel array 102 of the present disclosure. The solar panel array 102 is illustratively supported by a support post 104 extending upwardly from the ground 106. A bracket 108 couples the solar panel array 102 to the support post 104 for pivoting movement therebetween. An actuator (not shown) may be operably coupled to the bracket 108 to drive the solar panel array 102 in pivoting movement.

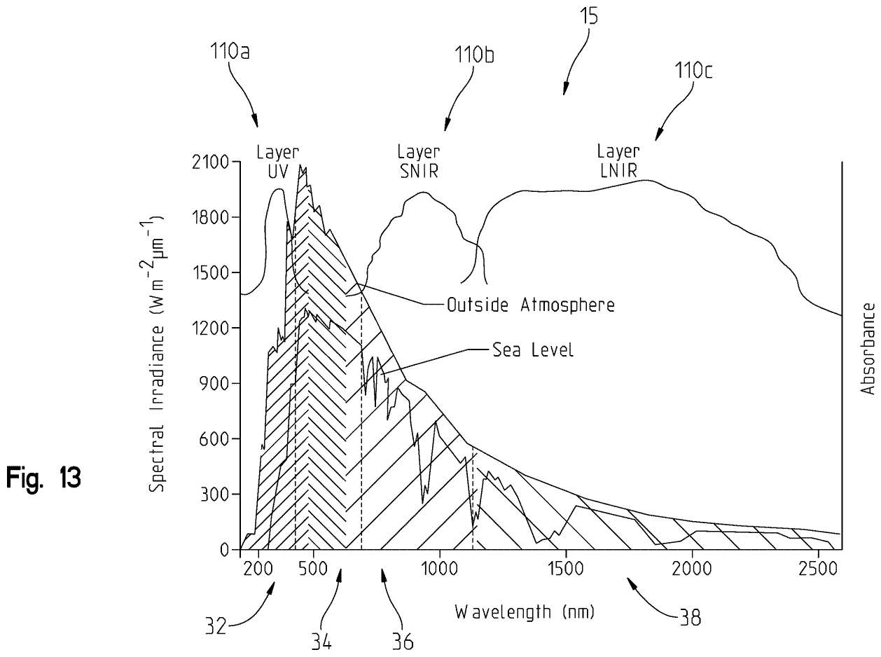

The illustrative solar panel array 102 includes a plurality of spaced apart, stacked panels 110a, 110b, 110c. The first panel 110a illustratively includes a first substrate 112a supporting a first photovoltaic layer 114a. More particularly, the first panel 110a is illustratively formed of a translucent polymer including a first or upper surface 116a, and a second or lower surface 118a. As further detailed herein, the first photovoltaic layer 114a is illustratively printed on the upper surface 116a. The first photovoltaic layer 114a is illustratively configured to absorb ultraviolet (UV) light (having wavelengths between 100 nm and 400 nm), and transmit visible light (having wavelengths between 400 nm and 700 nm) (FIG. 13). The first photovoltaic layer 114a is illustratively a first donor:acceptor material composition, such as a diketopyrrolopyrrole (DPP) based polymer for absorbing light having wavelengths between 100 nanometers and 400 nanometers. In an illustrative embodiment, the first donor:acceptor material composition is P3HT-DPP:Y6.

As used herein, absorbing light (i.e., absorbance) is defined as at least partially absorbing light of the desired wavelengths. Similarly, transmitting light (i.e., translucency) is defined as at least partially transmitting light of the desired wavelengths (e.g., at least 45% of the light passing therethrough).

The second panel 110b illustratively includes a second substrate 112b supporting a second photovoltaic layer 114b. More particularly, the second panel 110b is illustratively formed of a translucent polymer including a first or upper surface 116b, and a second or lower surface 118b. As further detailed herein, the second photovoltaic layer 114b is illustratively printed on the upper surface 116b. The second photovoltaic layer 114b is illustratively configured to absorb short-wave near infrared (SNIR) light (having wavelengths between 700 nm and 1100 nm), and transmit visible light (having wavelengths between 400 nm and 700 nm) (FIG. 13). The second photovoltaic layer 114b is illustratively a second donor:acceptor material composition, such as a thiophene-based polymer for absorbing light having wavelengths between 700 nanometers and 1100 nanometers. In an illustrative embodiment, the second donor:acceptor material composition is PBDB-T:Y6,

The third panel 110c illustratively includes a third substrate 112c supporting a third photovoltaic layer 114c. More particularly, the third panel 110c is illustratively formed of a translucent polymer including a first or upper surface 116c, and a second or lower surface 118c. As further detailed herein, the third photovoltaic layer 114c is illustratively printed on the upper surface 116c. The third photovoltaic layer 114c is illustratively configured to absorb long-wave near infrared (LNIR) light (having wavelengths between 1100 nm and 2500 nm), and transmit visible light (having wavelengths between 400 nm and 700 nm) (FIG. 13). The third photovoltaic layer 114c is illustratively a third donor:acceptor material composition, such as a PBDTTT derivative for absorbing light having wavelengths between 1100 nanometers and 2500 nanometers. In an illustrative embodiment, the third donor:acceptor material composition is PTB7:Y6.

In certain illustrative embodiments, a fourth photovoltaic layer 114d may also be supported by the third panel 110c. More particularly, the fourth photovoltaic layer 114d is illustratively printed on the lower surface 118c. As such, the fourth photovoltaic layer 114d opposes the third photovoltaic layer 114c and faces outwardly from the solar panel array 102. The fourth photovoltaic layer 114d is illustratively configured to absorb ultraviolet (UV) light (having wavelengths between 100 nm and 400 nm), and transmit visible light (having wavelengths between 400 nm and 700 nm). The fourth photovoltaic layer 114d is illustratively a first donor:acceptor material composition, such as a diketopyrrolopyrrole (DPP) based polymer for absorbing light having wavelengths between 100 nanometers and 400 nanometers. In an illustrative embodiment, the fourth donor:acceptor material composition is P3HT-DPP:Y6.

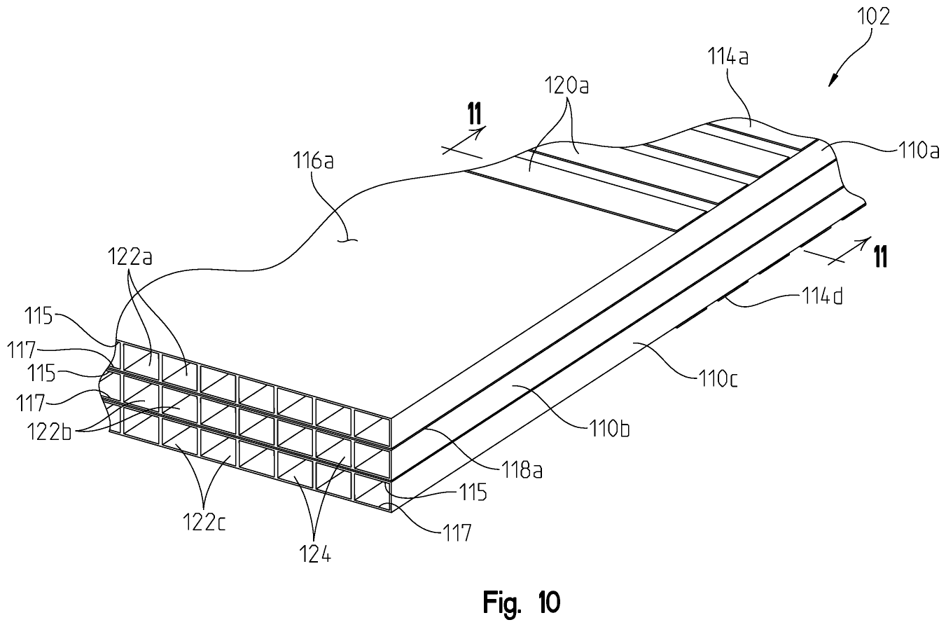

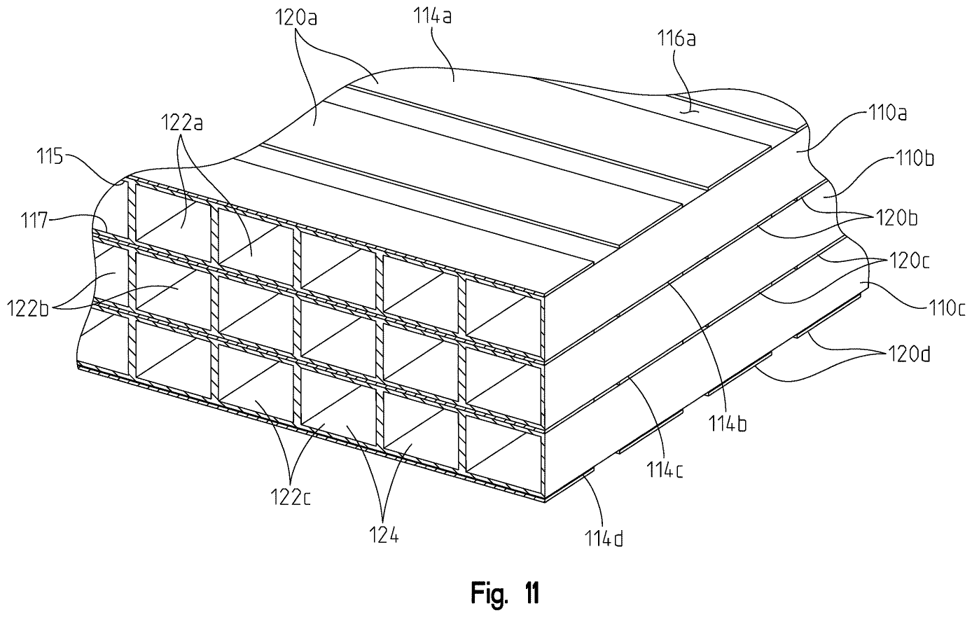

With reference to FIGS. 10 and 11, each illustrative substrate 112a, 112b, 112c is a twin-wall planar sheet including an upper layer 115 and a lower layer 117. The upper layer 115 defines respective upper surface 116a, 116b, 116c supporting spaced apart strips 120a, 120b, 120c of the photovoltaic layers 114a, 114b, 114c. A heat sink is illustratively positioned intermediate the upper layer 115 and the lower layer 117 of each substrate 112a, 112b, 112b. The heat sink is illustratively defined by a plurality of laterally spaced hollow channels 122a, 122b, 122c having opposing open ends 124 to permit airflow therethrough.

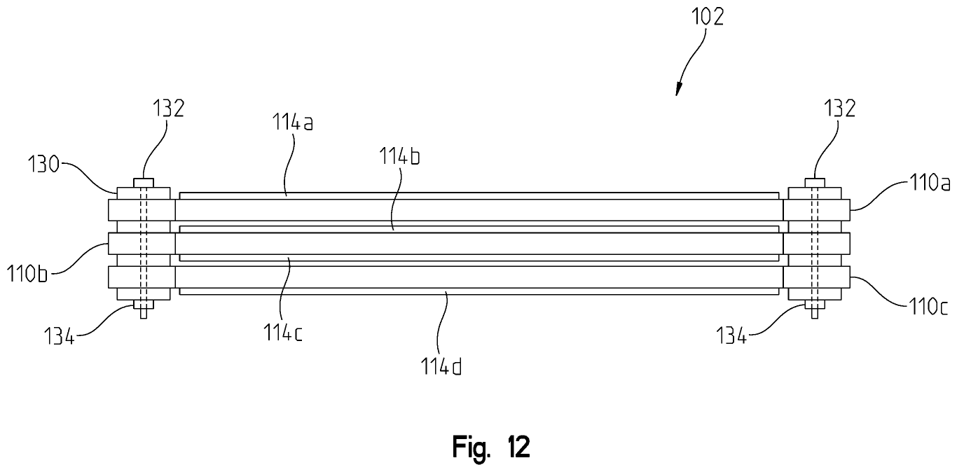

With reference to FIG. 12, each of the panels 110a, 110b, 110c of the solar panel array 102 coupled together via a frame 130. Bolts 132 and cooperating nuts 134 may secure the panels 110a, 110b, 110c to the frame 130. Illustratively, each photovoltaic layer 114a, 114b, 114c, 114d have a thickness of about 0.1 inches. The combined thickness of the first panel 110a, 110b, 110c is illustratively about 1 inch.

As further detailed herein, the solar panel array 102 has a light utilization efficiency (LUE) of at least 4.5%, and an average visible transmittance (AVT) of at least 45%.

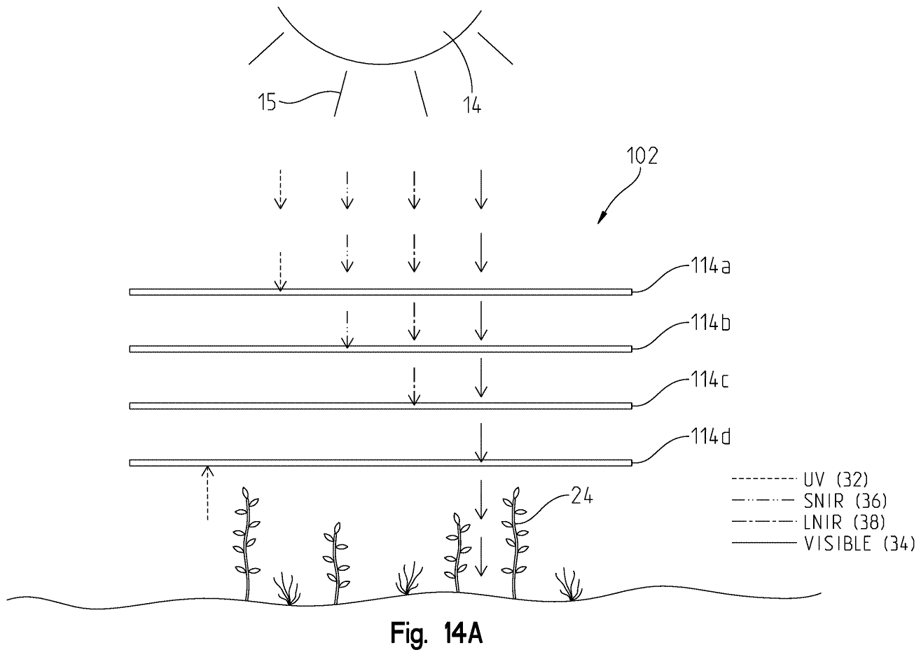

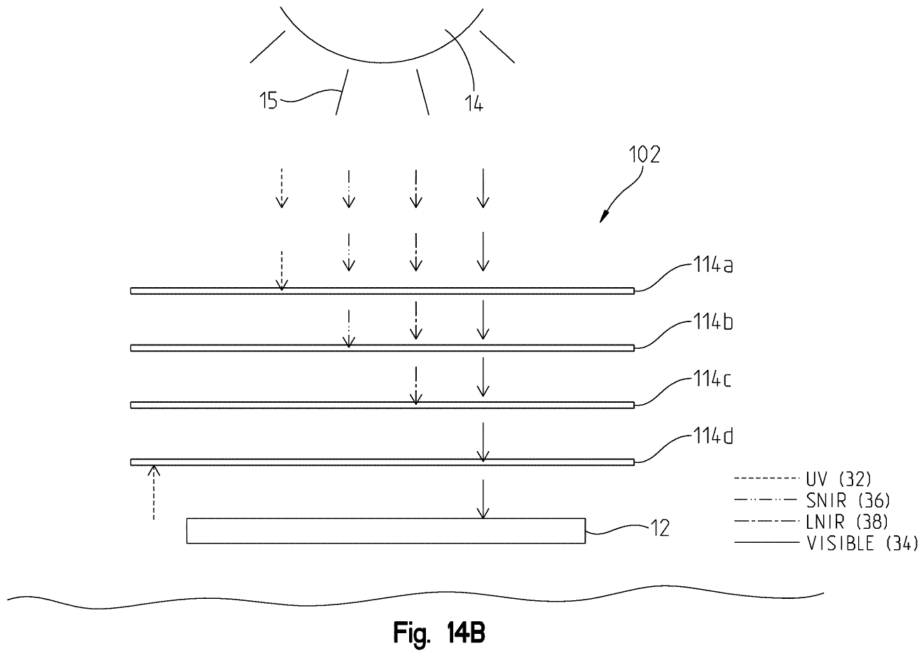

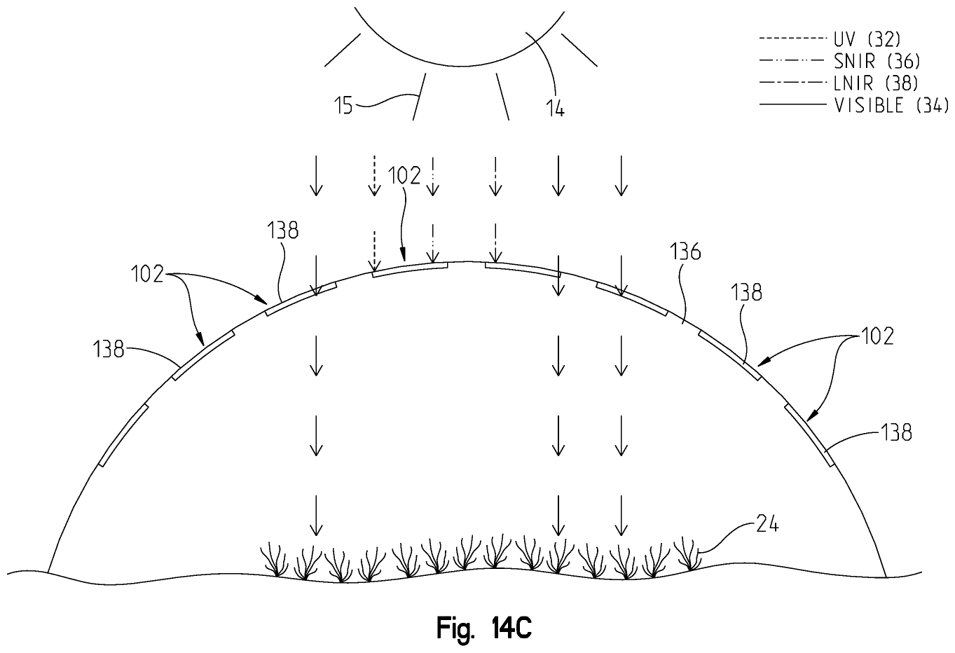

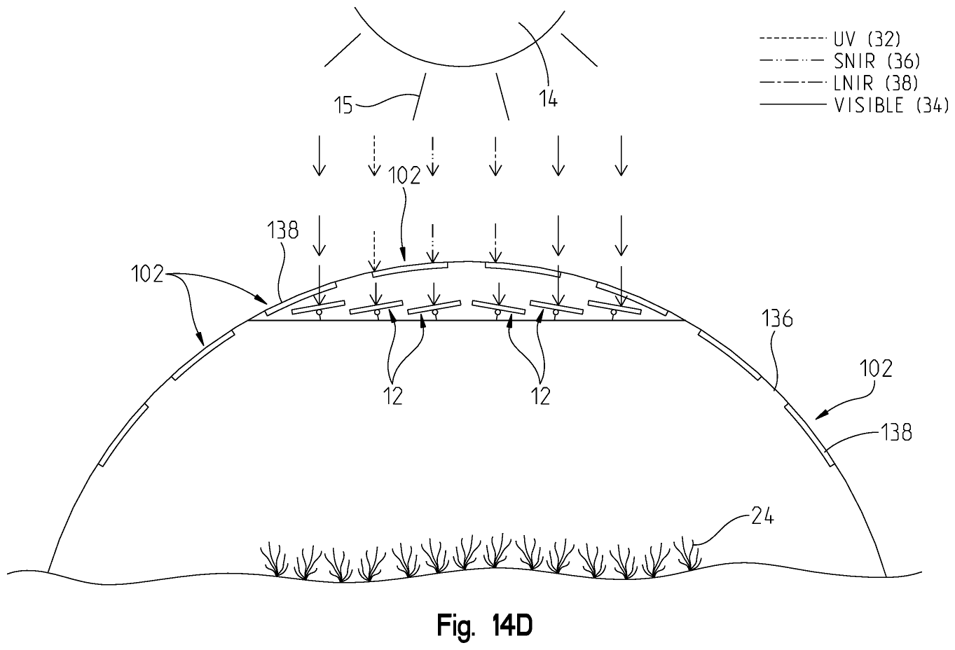

FIGS. 14A and 14B are diagrammatic views of illustrative light absorption and transmission through the photovoltaic layers 114a, 114b, 114c, 114d.

FIG. 14A shows visible light (wavelengths between 400 nm and 700 nm) passing through the photovoltaic layers 114a, 114b, 114c, 114d to vegetation 24. As further detailed herein, the layers 114a, 114b, 114c, 114d provide visible light transmissivity of at least 45%. Simultaneously, the photovoltaic layers 114a, 114b, 114c, 114d absorb at least some of the light in the ultraviolet (UV) range (100 nm to 400 nm), the SNIR range (700 nm to 1100 nm), the LNIR range (1100 nm to 2500 nm) and the ultraviolet (UV) range (100 nm to 400 nm), respectfully. FIG. 14B is similar to the arrangement of FIG. 14A but illustrates a conventional solar panel 12 positioned below the photovoltaic layer 114d for capturing remaining light passing through the solar panel array 102.

FIG. 14c illustrates a plurality of solar panel arrays 102 supported by a roof structure 136, illustratively by couplers such as brackets 138. The roof structure 136 may be part of a greenhouse, building atrium, or stadium, for example.

FIG. 14D illustrates a plurality of solar panel arrays 102 supported by the roof structure 136 and above conventional solar panels 12.

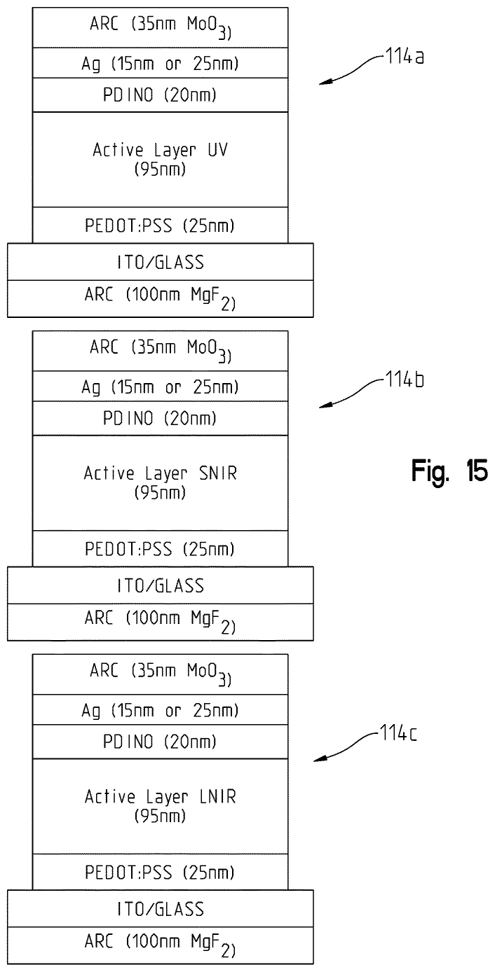

FIG. 15 is a diagrammatic representation of illustrative photovoltaic layers 114a, 114b, 114c of the solar panel array 102. As further detailed herein, each layer 114a, 114b, 114c have different spectral regions.

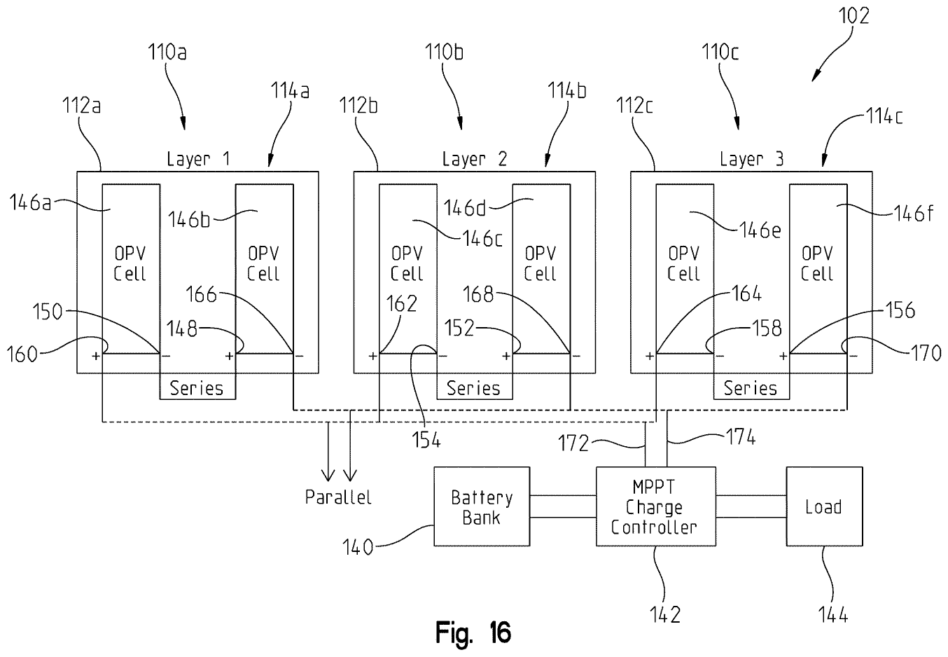

FIG. 16 is a schematic diagram of an illustrative solar cell arrangement 102 of the present disclosure that clarifies the differences between the present invention and tandem solar cells (TSCs), which use only two active layers within the same cell. A typical solar panel consists of multiple cells (e.g., silicon wafers) that are connected to each other and then encapsulated, typically by glass, to form the panels. The solar cells on a solar panel are typically connected in series to each other, meaning the positive terminal of one cell is connected to the negative terminal of the next, which results in an increased overall voltage output from the panel.

Solar cell arrangement 102 includes panels or layers 110a, 110b, 110c, a battery bank 140, a maximum power point tracking (MPPT) charge controller 142, and a load 144. Solar panel array 102 includes three layers 110a, 110b, 110c each including respective base or substrate 114a, 114b, 114c in the form of a polycarbonate sheet. On each of the three bases 114a, 114b, 114c are mounted a respective two of six organic photovoltaic (OPV) cells 146a, 146b, 146c, 146d, 146e, 146f. Cells 146a, 146b, 146c, 146d, 146e, 146f may be created by a 3D printer. Cells 146a, 146b, 146c, 146d, 146e, 146f are connected to each other in series within each layer 110a, 110b, 110c. That is, cells 146a, 146b are connected to each other in series, meaning that positive terminal 148 of cell 146b is electrically connected to negative terminal 150 of cell 146a; cells 146c, 146d are connected to each other in series, meaning that positive terminal 152 of cell 146d is electrically connected to negative terminal 154 of cell 146c; and cells 146e, 146f are connected to each other in series, meaning that positive terminal 156 of cell 146f is electrically connected to negative terminal 158 of cell 146e.

For clarity of illustration, only two OPV cells 146 are shown as being printed on each polycarbonate sheet 114. However, depending on the width of the sheet 114, there may be a dozen or more of these cells 146 on each polycarbonate sheet 114. The layers 110 are connected to each other in parallel, meaning that the higher voltage positive terminal in each layer (i.e., positive terminals 160, 162, 164) are connected to each other, and the lower voltage negative terminal in each layer (i.e., negative terminals 166, 168, 170) are connected to each other. Positive terminals 160, 162, 164 are connected to MPPT charge controller 142 at 172, and negative terminals 166, 168, 170 are connected to MPPT charge controller 142 at 174. This parallel connection of the layers results in an increased overall amperage output from the 3D OPV panel 12. The parallel connection may advantageously minimize the impact from mismatched voltages, which likely will exist between the different layers. Such a mismatch may be due to stacking up the sheets 114 on top of each other and due to the different active layer used in each layer's cells to capture wavelengths of the sun in different regions. MPPT charge controller 142 may further manage the mismatched voltages when charging the bank of batteries 140. Excess voltage that cannot be stored in battery bank 140 may be converted to current (amperage) to load 144.

Although the invention has been described as including regular OPV cells, it is within the scope of the invention to use tandem solar OPV cells on each layer, which may take advantage of the increased efficiency of TSCs so long as they allow the visible light to pass through (which they are not yet capable of at this point in time).

Printed solar panels have a better temperature coefficient than silicon-based panels, meaning that their efficiency is less affected by high temperatures and they will lose a smaller portion of their performance when it gets too hot. Although third-generation panels have a shorter lifespan as compared to first- and second-generation panels, they have the fastest payback time because of their much lower initial implementation cost. Use of advanced substrate materials, such as Dyneema Composite Fabric, has led to significant improvements in longevity of these panels but more needs to be done in this regard.

Currently, printed solar cells have the life span of about 10 years with an efficiency about 10%, whereas traditional silicon solar PV cells are closer to 25% efficient and typically have a 25-year warranty. So, in order to reach competitive commercial viability, research is needed for third-generation panels to increase their efficiency and durability.

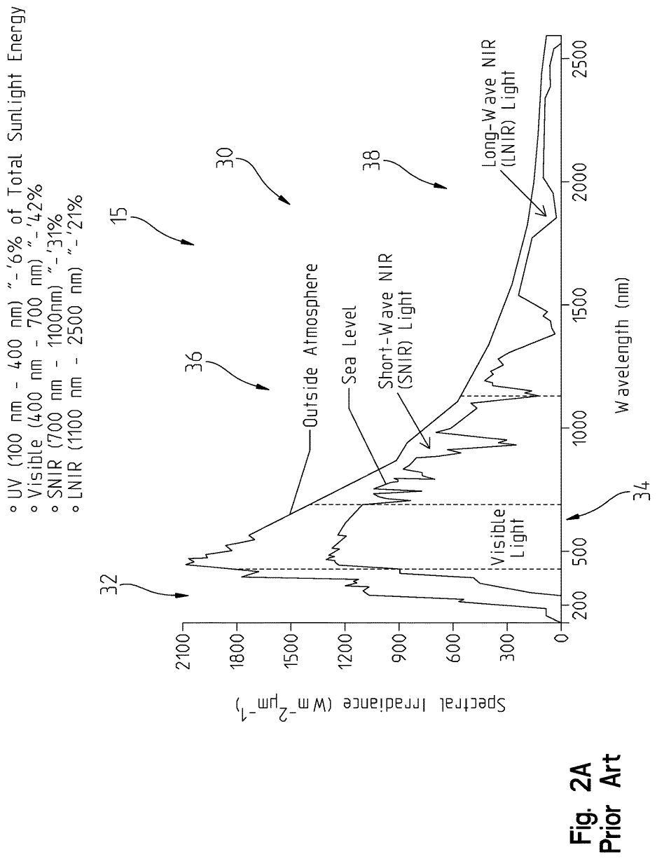

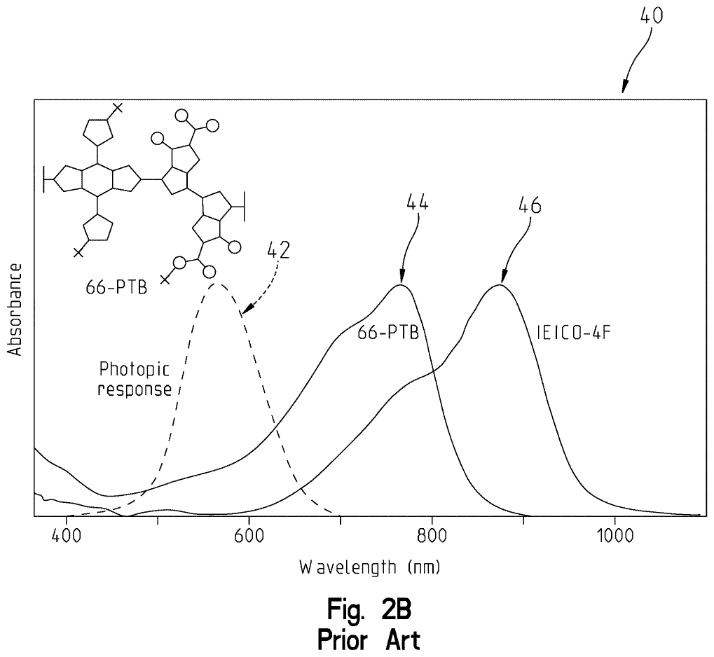

Printed three-dimensional (“3D”) solar panels which have high efficiency and durability as compared to currently available solar panel options: As indicated above, the efficiency of the third-generation panels is currently low, but they are made using non-toxic organic materials, can be printed on any surface using different patterns and transparency, and production can be easily scaled. 8 mm thick multi-wall 8′ long and 4′ wide Polycarbonate sheets (see FIGS. 2A and 2B) are used as separators to stack up several ultra-thin printed solar cells. The final weight of each 8′×4′ solar panel is less than 2.5 pounds, which is a fraction of the weight for comparable-sized first- or second-generation panels. The printed solar cells can be made either transparent, so that light gets to layers below, or printed in different patterns so that the thin film above allows lights to come in between the printed layer down to the next thin-film printed layer below. In one embodiment, the 3D solar panel yields close to the 25% efficiency of the current bi-facial silicon solar panels. Furthermore, having a more rigid backbone that helps diffuse light to lower layers but protects the thin film against the elements while still maintaining the lower weight advantage of these panels goes a long way in adoption of this technology for commercial applications such as agrivoltaics (i.e., use of land for dual purpose of generating electricity while improving faming by use of a canopy over crops).

In another illustrative embodiment, the present disclosure relates to a printing process for printing 3D solar panels. The printing process produces the expected amount of electric energy to achieve higher efficiency. Temperature rise on the surface of the solar panels may have a major negative impact on efficiency. As detailed above, multi-wall polycarbonate sheets are transparent and allow passage of air through their channels, which has a natural cooling effect, as opposed to silicon panels that are encapsulated in glass and lose efficiency when their surface gets hot.

The following is an exemplary method for a first phase of evaluating the efficiency of printed 3D solar panels: In another embodiment, the present disclosure relates to a printing process for printing 3D solar panels.
1. Place solar ink on both sides of a multi-wall polycarbonate sheet to create a bi-facial printed panel and determine improvements in efficiency. Since light must get to the crops underneath for agrivoltaics use cases, only print in the middle half of the sample. Using sensors, determine how the light is diffused under the sample and the impact of sample-surface temperature rise on efficiency. Compare the results with first-(silicon) and second-generation (CdTe) samples.
2. Create cloudy conditions in the lab using ambient light instead of direct light and evaluate the drop in efficiency between the bi-facial silicon, the CdTe, and the bi-facial printed samples to determine if printed panels perform better under cloudy conditions.
3. If printed sample performs comparatively better than silicon and CdTe samples under cloudy conditions, evaluate all three samples for direct versus indirect sun light. Silicon panels are most efficient when the sun's rays hit the surface at a 90-degree angle. If the printed panels on multi-wall polycarbonate sheets perform better with indirect ray, then the need for solar trackers is reduced.
4. Next, create printed 3D panels by using three 8 mm thick polycarbonate sheets that are stacked up on top of each other and linked using UV curing adhesive (the total weight will be less than 8 pounds). The middle layer will be the bi-facial printed panel whereas the outer layers will have printed circuit on the outward face. Try different patterns of printing and/or different transparencies of the printed material on different layers to maximize efficiency. (The figures illustratively show three polycarbonate sheets slightly apart for clarity whereas the actual samples will be bonded together using UV curing adhesive, which dries clear when exposed to UV light.)
5. Try different wall thickness for polycarbonate sheets to determine if a thinner wall thickness (for instance using 6 mm instead of the 8 mm) would make a difference in performance. A thinner sheet is less expensive, lighter in weight, and will allow more light to pass through. Also, thinner sheets allow stacking of more layers without increasing the weight or thickness of printed 3D panels (e.g., four 6 mm sheets will have the same thickness and weight of three 8 mm sheets but will increase efficiency).
6. Operational stability against exposure to water vapor, oxygen, dirt, and UV irradiation (requiring proper encapsulation) can also be studied but the main evaluation for these “weatherability” factors can be done in a second phase after deployment in the field.

In a second phase evaluation, create full-sized printed panels and try them out in a farm for any items in the list above that require further validation. Use IoT sensors to monitor the effects on the crops and compare the impact of a printed-panel canopy against canopies made of standard silicon-based solar panels and CdTe panels. If all the evaluations in the two phases above prove that use of multiple polycarbonate sheets with printed solar layers increases efficiency to the expected level, a third phase can focus on creating an appropriate lattice structure for the walls of the polycarbonate sheets to maximize diffusion of light in all directions and thus expand the improvements. The third phase can involve investigating the creation of printed 3D solar panels within a spectrum that doesn't compete with or can co-exist with the wavelengths of light that plants need for healthy growth.

Furthermore, it can explore the feasibility of using these printed 3D panels for electricity-producing greenhouses, which is a natural evolution since multi-wall polycarbonate sheets were created mainly for building greenhouses. Several versions of “agrivoltaics greenhouses” already exist using first- and third-generation low-efficiency panels, which makes it straightforward to compare with the proposed “printed 3D-solar greenhouse”.

Advantages and disadvantages of existing printed third-generation solar cells are captured in Table 1:

TABLE 1

| Advantages of Printed Panels | Disadvantages of Printed Panels |
|---|---|
| Inexpensive and lightweight, making them | Limited efficiency of around 10% compared to |
| ideal for cost-effective agrivoltaics projects | first- and second-generation panels at 20+% |
| Less pollutant and more convenient to | Durability issues with lifespan of 10 years with |
| manufacture using roll-to-roll printing | exposure to UV light, oxygen, and moisture |
| More efficient in cloudy conditions, which | Sensitivity to extremely high temperatures and |
| also minimizes the need for a solar tracking | may degrade or malfunction in extreme heat |
| Better performance at high temperatures since | Still in research and development with many |
| efficiency is not lost as much with heat | unknown factors in materials and production |
| Can be printed at different transparencies and | Unproven technology for agrivoltaics since no |
| sizes making them ideal for agrivoltaics | canopies of this type have ever been tried |
| Eco-friendly and easy to dispose of or recycle | Low production volume and less commercially |
| because of non-toxic biodegradable material | viable due to lack of availability of printed |
| | panels |

The proposed 3D panels, addressing many of the current disadvantages of the third-generation solar cells, could become by far the least expensive and most appropriate type of all solar panels, especially for agrivoltaics projects. This is because they need less canopy structure, can cover a much larger area over crops due to high transmissivity, generate less waste, can be printed in different transparencies, and are easier to manufacture. Also, because of their lightweight nature and flexibility, the 3D third-generation printed panels of the present disclosure are easier to form and install as a canopy than first- or second-generation cells; which decreases the installation cost, making them even more economical.

The raw materials used to produce these printed 3D solar panels are cost effective, the manufacturing process is comparatively simpler and cleaner, these solar cells work well in cloudy weather, they weigh a fraction of standard solar panels, are easier to form and install, and are easily recyclable in contrast with previous generations of solar panels. Although the focus of this disclosure is on agrivoltaics, because of economic benefits to farmers as well as climate impact and sustainability, the results from this invention have the potential to expand the general market for printed solar panels and thus greatly contribute to the commercial success of third-generation solar cells and possibly revolutionize the solar energy industry.

As is known, light is made up of single energy particles called photons. Every photon within the visible spectrum (i.e., 400 nm to 700 nm) has the potential to drive photosynthesis. Light quality refers to the spectral distribution of light, or to the relative number of photons in the blue, green, red, far-red, and other parts of the spectrum emitted from the sun. The energy of each photon depends on its wavelength. Photons with shorter wavelengths, such as ultraviolet (UV) light, have more energy than photons with longer wavelengths, such as red light. The wavelength of light is most commonly measured in nanometers (nm), or billionths of a meter. Blue light is generally considered to be the part of light with wavelengths between 400 and 500 nm. Blue light, green light (500 to 600 nm) and red light (600 to 700 nm) make up the spectrum mainly used for photosynthesis (400 to 700 nm). About 43% of the energy from the sun is in the photosynthetic visible band (see FIG. 2A). The remaining energy has shorter wavelengths (e.g., ultraviolet at about 6%) or longer wavelengths (e.g., infrared radiation at about 51%). Here is a list of how visible spectrum and photosynthesis are related:
700-800 nm—this increases the rate of photosynthesis and can promote extension growth.
610-700 nm—this is ideal for chlorophyll absorption, germination, flower and bud development.
510-610 nm—this green light helps with photosynthesis and the size and weight of plants.
400-510 nm—light that plays a significant role in plant quality, root development and chlorophyl absorption.
315-400 nm—the longest UV light wavelength that enhances plant pigmentation, and thickens leaves.
280-315 nm—ultraviolet light that has a negative impact on plant growth.

In order to achieve photosynthesis in the design of 3D OPVs, we have control over molecular characteristics, their donor/acceptor ratio, their component thickness, their reflection and refraction within the structure of each cell, their layout pattern, and the manufacturing process. For instance, to maximize transmittance, we can use a donor:acceptor active layer made of PM6:Y6 with ITO as the anode (i.e., top electrode) and silver (Ag) nanowires of a thickness of 15 nm as the cathode (i.e., bottom electrode), which has a transmittance of 90%. We can also use ARC (Antireflective Covering) thin-film coating outside of the top and bottom electrodes to reduce reflection at layer interfaces (see FIG. 15). Furthermore, these materials can be prepared by solution processing and are compatible with various production methods such as spin coating, inkjet printing, and additive manufacturing.

Once one complete cell with appropriate transmissivity and controlled-range absorption has been attained, we will start working on the next cell with a complementary absorption spectrum that doesn't compete with the previous cell for wavelengths needed to generate electricity (see FIG. 15). For instance, we can use PTB7-Th:Y12 as donor:acceptor active material with different thickness of the silver nanowire cathode. In effect, we are creating a high efficiency panel through the optical management of multiple cell structures that are stacked on top of each other. Each cell is separated from the next cell by use of thin twin-wall polycarbonate layers to allow passage of air through its channels and act as a heat sink for cooling purposes (see FIGS. 10 and 11). We can use other types of heat sinks if the temperature rise within the cells requires it. Note that “narrow bandgap absorption” and “narrow region of wavelengths needed to generate electricity” are related but not exactly the same. Materials with a narrow bandgap can effectively absorb lower-energy (longer wavelength) photons, which is beneficial for harvesting more of the solar spectrum. A narrow region of wavelengths needed to generate electricity, on the other hand, implies a limited range of wavelengths that can produce charge carriers (electrons and holes) to create an electric current. This can be influenced by the bandgap but also involves other factors such as the efficiency of charge separation and collection in the solar cell.

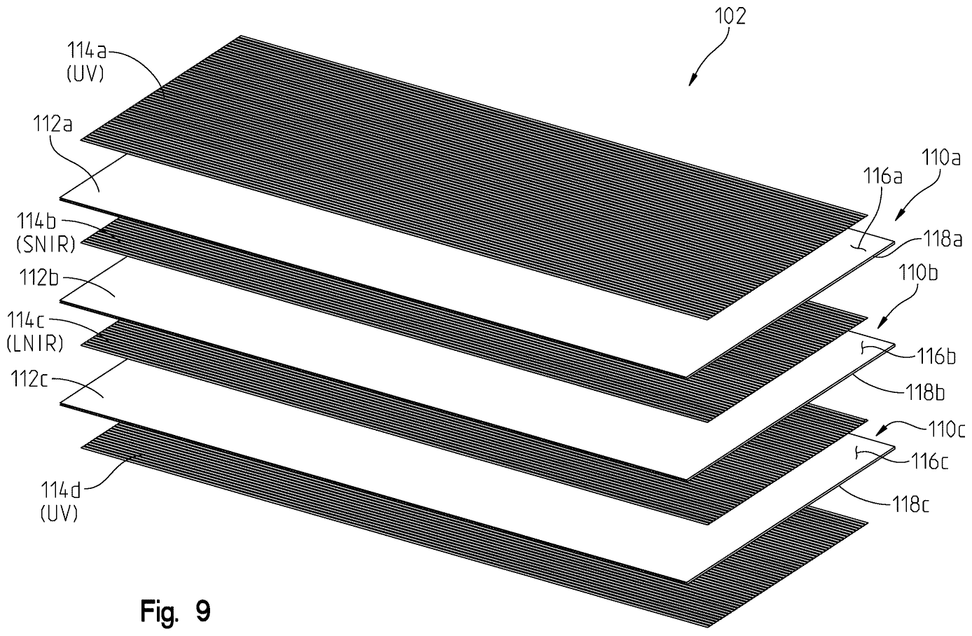

As indicated above, third-generation panels have low efficiency but their transparency is tunable and they are made of non-toxic organic materials, they can be printed on any surface using different patterns, and their production can be easily scaled. We plan to initially use 8 mm thick twin-wall 8′ long by 4′ wide polycarbonate sheets (see FIG. 9) as separators to stack up several ultra-thin printed solar cells. The final weight of each 8′×4′ solar panel would be less than 2.5 pounds, which is a fraction of the weight for a comparably-sized first- or second-generation panel.

The OPV cells are made as transparent as possible with complementary controlled-range absorbance, so that light gets to layers below. They could also be printed in different patterns so that the thin film above allows light to come down to the next printed layer below. Eventually, the entire 3D OPV panel could be created autonomously via additive manufacturing. The overall objective is to get much closer to the 25% efficiency of the current bi-facial silicon solar panels specifically for agrivoltaics, which can be attained with our proposed design since OPVs perform well under both direct and diffuse sun radiation, and the amount of coverage of the canopy over the crops can be much larger due to the high transmissivity of 3D OPV panels. Since we will eventually use additive manufacturing for construction of 3D OPVs, we can consider a lattice structure within the twin-wall polycarbonate sheet to improve light transmission and cooling. Finally, we will pay special attention to how cells are connected within a layer and how different cells and layers are connected in this system to minimize the mismatch between voltages and amperages within and between layers. We will use bypass diodes to help mitigate losses caused by shading or voltage mismatches since the cells on the same layer are connected in series. We will connect the different layers in parallel since use of different active organic material in different layers would most likely lead to mismatched voltages. We will also implement a maximum power point tracking (MPPT) solar charge controller in the overall system to optimize the power output from each layer, helping to account for voltage differences and maximizing overall efficiency.

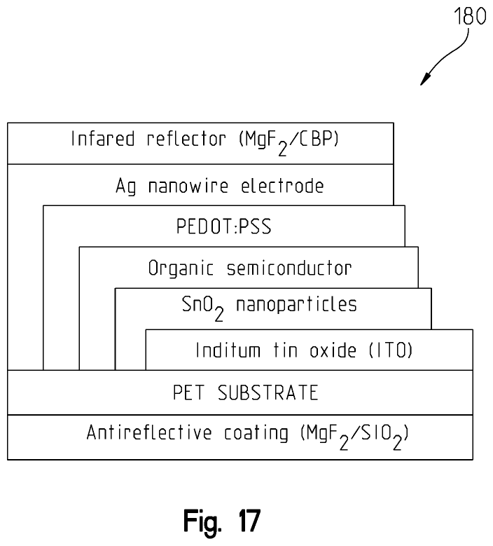

FIG. 17 is a diagrammatic view of an illustrative printed semi-transparent printed organic solar cell 180.

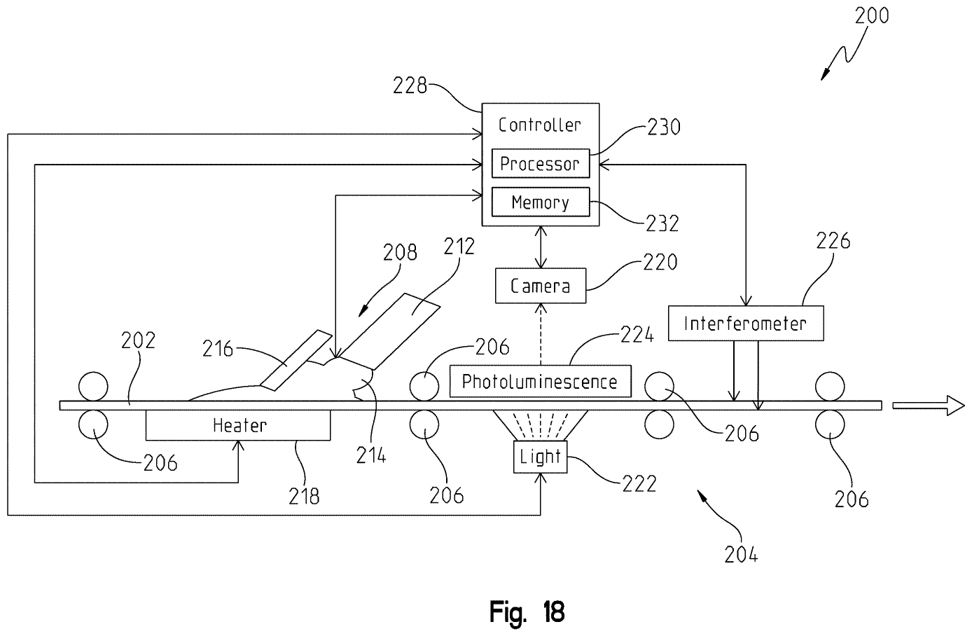

FIG. 18 shows the schematics of the in-situ monitoring system during manufacturing. More particularly, a manufacturing system 200 is configured to process a substrate 202 to form one or more of the solar panels 110a, 110b, 110c. The in-situ monitoring system 204 monitors the processing the substrate 202 as it is moved through the system 200 by a conveyor, illustratively a plurality of motor driven rollers 206. An applicator 208 applies a liquid photovoltaic material to the substrate 202 to define one of the photovoltaic layers 114a, 114b, 114c, 114d. The applicator 208 illustratively includes a pump 212 cooperating with a syringe 214. A movable blade 216 cooperates with the syringe 214 to control thickness of the layer 114a, 114b, 114c, 114d.

A heater 218 is illustratively positioned below a lower surface of the substrate 202 opposite the applicator 208. A camera 220 and a light source 222 are positioned downstream from the applicator 208 on opposite sides of the substrate 202. The camera 220 may detect light (e.g., photoluminescence 224) on an opposite side of the substrate 202 from the light source 222. An interferometer 226 may be positioned downstream from the applicator 208 to measure thickness of the layer 114a, 114b, 114c, 114d.

A controller 228 is illustratively in electrical communication with the applicator 208, the heater 218, the camera 220, the light source 222 and the interferometer 226. The controller 228 includes a processor 230 and a memory 232 having software with machine readable instructions for execution by the processor 230.

The camera 220 combined with the light source 222 will obtain the spatial map of transmitted light intensity. Local high light intensity will indicate pinholes in the printed films. The interferometer 226 will be used to measure the thickness of the printed film. Because light reflection from the semiconductor/SnO2 interface will be dominant as compared to other interfaces underneath, the thickness of the semiconductor layer, which is the most critical layer, can be monitored accurately. The information obtained from the monitoring system 204 may be provided to a GenAI (Generative AI) model in the controller 228 for updated selection of photovoltaic material.

Organic solar cells show unbeatable weight-to-power ratio and bulk heterojunction (BHJ) donor:acceptor materials are the most promising when mass production is achieved. As stated before, OPVs are the clear winner for agrivoltaics application because of their non-toxicity, potential low production cost, light weight, and minimal environmental impact, but their spectral tunability is the main attraction in our context. The outdoor performance of OPV modules has been assessed under real environmental conditions, where the efficiency of OPV panels was below 4%, which is significantly less than 20% measured for silicon panels of similar size they tested under the same conditions. OPV modules have demonstrated a good capability in converting diffuse irradiance to electric power, providing a reason to pay closer attention to transmittance, reflectance, and absorptance of the materials we consider in this invention. Therefore, when considering solar panels for agrivoltaics application, we will pay close attention to Light Utilization Efficiency (LUE), which is defined as:

$$LUE = AVT \times PCE$$

Where AVT is the average visible transmittance through the panels, typically measured by a Spectroradiometer (Rodriguez-Martinez, 2023), and PCE is the power conversion efficiency:

$$PCE = {P}_{max} / ( {G}_{meas} \times {A}_{cell} )$$

Where Pmax is the maximum power produced by 3D OPV module, Gₘₑₐₛ is the actual solar irradiance for the region, and A_{cell} is the area covered by the OPV cells. Maximizing LUE is one of the main objectives of this invention. Note that there is a trade-off between AVT and PCE for current commercial organic panels (i.e., there is less efficiency for more transparent panels), but our innovation is aiming to change the status quo and create a transparent panel for agrivoltaics applications that has a comparable efficiency to silicon panels when taking into account the fact that the canopy coverage over the crops will be much higher due to transmissivity of 3D OPVs.

Among all the currently available and emerging solar cells, organic solar cells have the potential for the best LUE. For example, organic solar cells have been created with LUE of 5%, surpassing the performance of both inorganic and perovskite-based semitransparent photovoltaics (which have peak LUE values of approximately 2.5% and 2%, respectively). Theoretically, organic solar cells can achieve an LUE of about 20% by only utilizing photons in the UV, near-IR, and IR spectrum. On the other hand, it is reported in literature that an AVT of 34% for OPV panels on a canopy over crops was essentially consistent for growth of plants under sunlight. Furthermore, many marketing materials indicate that PCE should be at least 10% to make OPV panels commercially viable. Therefore, we are seeking a design that gives us an AVT above 45% and an LUE above 4.5% for agrivoltaics projects. Given the theoretical possibilities, we are confident the uniquely designed 3D OPV can achieve these objectives.

In addition to the best LUE, the manufacturing process of organic solar cells requires much less embodied carbon than that of silicon solar cells. The required embodied carbon of organic solar cells is 5 to 7 g/kWh, whereas that of silicon solar cells is 50 g/kWh. This is mainly because in the conventional manufacturing of silicon solar cells, silicon needs to be melted at higher than 1000 degree Celsius. In contrast, organic solar cells can be produced at a temperature lower than 150 degrees Celsius. This benefit is in addition to the facts that silicon and cadmium must be mined, which adds to the carbon footprint, and require a clean room for processing. Furthermore, in combination with transmissivity and carbon footprint, the weight of panels determines the overall lifecycle cost and benefits. Conventional silicon solar panels are heavy (10.7 kg/m2 or 20 W/kg) and require sturdy supporting structures in agrivoltaics applications. On the other hand, organic solar cells on plastic films are comparatively lightweight (0.105 kg/m2 or 370 W/kg) and require a light support structure with a comparatively smaller footprint, which reduces the overall lifecycle cost and impedance of farm machinery movement. Finally, the biodegradable nature of organic cells and their simple recyclability could bring additional end-of-life savings and environmental benefits.

Following is a list of development phases in this invention. In the first phase:
1. Place existing commercial OPV panels (on both sides of a twin-wall polycarbonate sheet to create a bi-facial OPV panel and determine improvements in LUE. Since we need light to get to the crops under canopy for our use cases, we will place several one-foot wide OPV panels on the 4-feet wide polycarbonate sheet. We will use this as the benchmark for comparison with our innovative 3D OPV panels. We will also compare the efficiency and transparency results of existing commercial OPVs with bi-facial first-(silicon) and second-generation (CdTe) panels.
2. Create cloudy conditions in the lab using ambient light instead of direct light and evaluate the drop in efficiency (i.e., LUE) between the bi-facial silicon, the CdTe, and the bi-facial OPV panel to determine which panels perform better under cloudy conditions.
3. If bi-facial OPV panels perform comparatively better than silicon and CdTe samples under cloudy conditions, evaluate all three samples for direct versus indirect sun light. We know that silicon panels are most efficient when the sun's rays hit the surface at a 90-degree angle. If our bi-facial OPV panels on twin-wall polycarbonate sheets perform better with indirect rays, then the need for solar trackers is reduced.
4. Study the operational stability of the bi-facial OPV panel against exposure to water vapor, oxygen, dirt, and UV irradiation (requiring proper encapsulation) in the field.

In the next phase, we will test the multi-layer 3D panels by using three 8 mm thick polycarbonate sheets that are stacked up on top of each other and linked using UV curing adhesive (current prototype utilizes wooden frames to link layers). The panel on each layer is made up of cells generating electricity within controlled range of spectrum using Ultraviolet (UV) in 100-400 nm, short-wave Near Infrared (SNIR) in 700-1100 nm, and long-wave Near Infrared (LNIR) in 1100-2500 nm wavelengths of sunlight spectrum (see FIG. 9). We will also try different patterns of printing and different absorbance frequencies and transparencies of the printed material on each layer to maximize LUE. FIG. 9 shows the three polycarbonate sheets slightly apart for clarity whereas the eventual commercial version will be made by additive manufacturing and bonded together using UV curing adhesive, which dries clear when exposed to light.

In the second phase of the invention, we will:
1. Examine and validate the feasibility of using the multi-layer 3D OPVs with polycarbonate substrate for electricity-producing farms.
2. Create full-sized 3D panels and place them on the canopy in the farm and then test any items in the list above that require field testing.
3. Use IoT sensors under the canopy to monitor the effects on the environment and study the impact of an OPV canopy on the crops and soil.
4. Demonstrate compatibility of created 3D cells within a spectrum that does not compete with the wavelengths of light that plants need for healthy growth.

Some aspects of the invention include creating AI empowered computer systems and using the same to aid in the identification, design and synthesis of organic material such as organic polymers that can be used to fabricate agrivoltaics solar cells. Identifying existing molecules and/or creating new molecules for use in fabricating solar cells is challenging. Identifying and/or creating material suitable for use in manufacturing agrivoltaics solar cells is especially challenging at last in part because materials in this space must both absorb electromagnetic energy in one or more regions of the electromagnetic spectrum and transmit sufficient energy in the region of the spectrum between about 400 to about 700 nanometers to support efficient plant growth in the shadow of the agrivoltaics instillation. It is currently understood that material for use agrivoltaics should exhibit at least 45% transmittance of light in 400 to about 700 nanometers region of the spectrum. Previously, printed electrodes such as Ag, poly(3,4-ethylenedioxythiophene)-poly(styrenesulfonate) (PEDOT:PSS), and inditum tin oxide (ITO), have been commonly used for semi-transparent organic solar cells. Ag and PEDOT:PSS electrodes block light with a wavelength of 400 nm to 700 nm. ITO electrodes have a better transparency than Ag or PEDOT:PSS and therefore will be studied in this invention to determine if they provide more light for photosynthesis of crops when cells are equipped with this type of electrodes. Also, spin coating will be used to create an ultra-thin (e.g., 15 nm) layer of Ag, which is almost as transparent as ITO.

Some aspects of the invention include identifying and/or developing polymers that act as donor and acceptor in the active layer of organic photovoltaic solar cells with absorbance in the ultraviolet (i.e., 100 to 400 nm), short-wave near infrared (i.e., 700 to 1100 nm) and long-wave near infrared (i.e., 1100 to 2500 nm) range of spectrum but allow the visible light to come through and reach the crops for our agrivoltaics application. There are a few candidate materials available such as P3HT-DPP:Y6 for partial UV absorption, PBDB-T:Y6 for partial short-wave near infrared absorption, and PTB7:Y6 for partial long-wave near infrared (1100 to 1500) with further optimization needed to reach 2500 nm.

Currently methods for identify and/or designing organic acceptors and organic donors include carefully reviewing the existing literature to identify organic molecules with the requisite properties of selective absorbance and transmittance. A recent manual review of some databases only identified two set of organic acceptors and donors. This review also identify some acceptors and some donors that exhibit the requisite absorbance transmittance for use in the fabrication of organic based agrivoltaics, Table 2, and attendant structures.

TABLE 2

| | | | | Absorption | Reference |
|---|---|---|---|---|---|
| | | | Absorption | max in | paper |
| # | Type | Material | wavelength(nm) | film(nm) | number |
| 1 | Acceptor | F6IC; F8IC; F10IC | 650-1000 | F6IC: 800 | 75 |
| | | | | F8IC: 862 | |
| | | | | F10IC: 862 | |
| 2 | Acceptor | IDT-T-N | <300-400; 560-800 | 750 | 94 |
| 3 | Acceptor | ITVC; ITVfIC; ITVffIC | 600-900 | 730 | 35 |
| 4 | Acceptor | IHIC | 600-1000 | 800 | 52 |
| 5 | Acceptor | NAI-FN-NAI | <300-500 | 430 | 72 |
| | Acceptor | NAI-FCN-NAI | <300-500 | 350&450 | 73 |
| 6 | Donor:Acceptor | PTB7-Th:IHIC | 500-950 | 700&800 | 52 |
| 7 | Donor:Acceptor | PTB7-Th:IEICO-4F | <300-400 | 300&700&870 | 87 |
| | | | 550-1000 | | |

Chemical structure for some of the molecules listed in Table 2, are as follows:

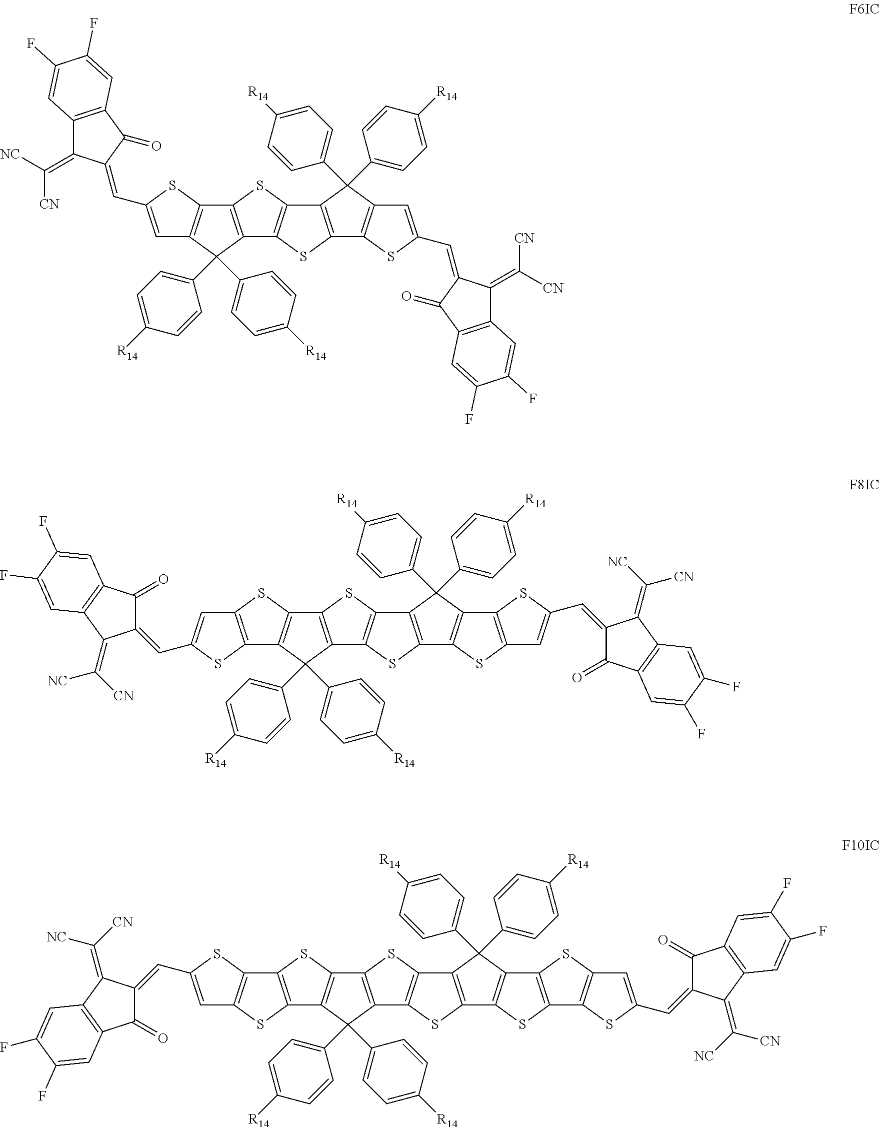

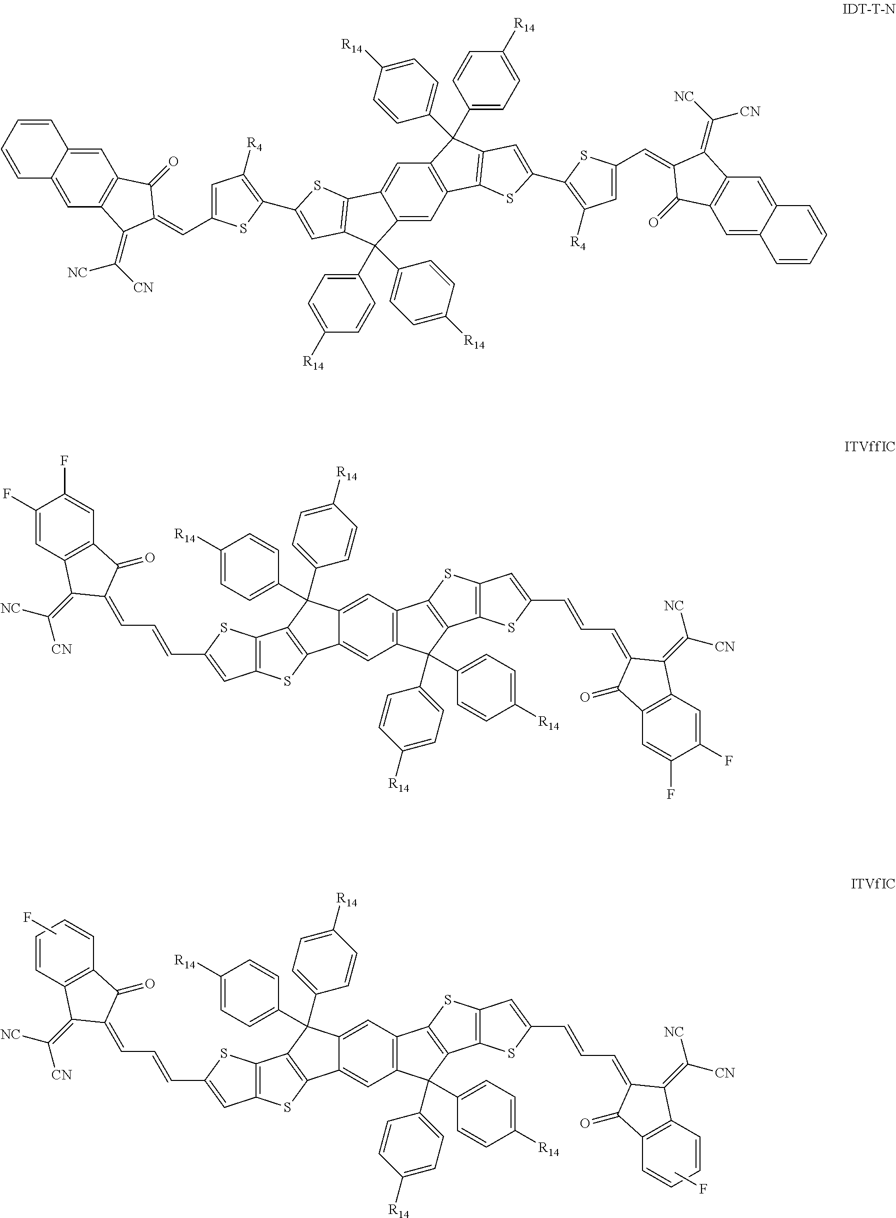

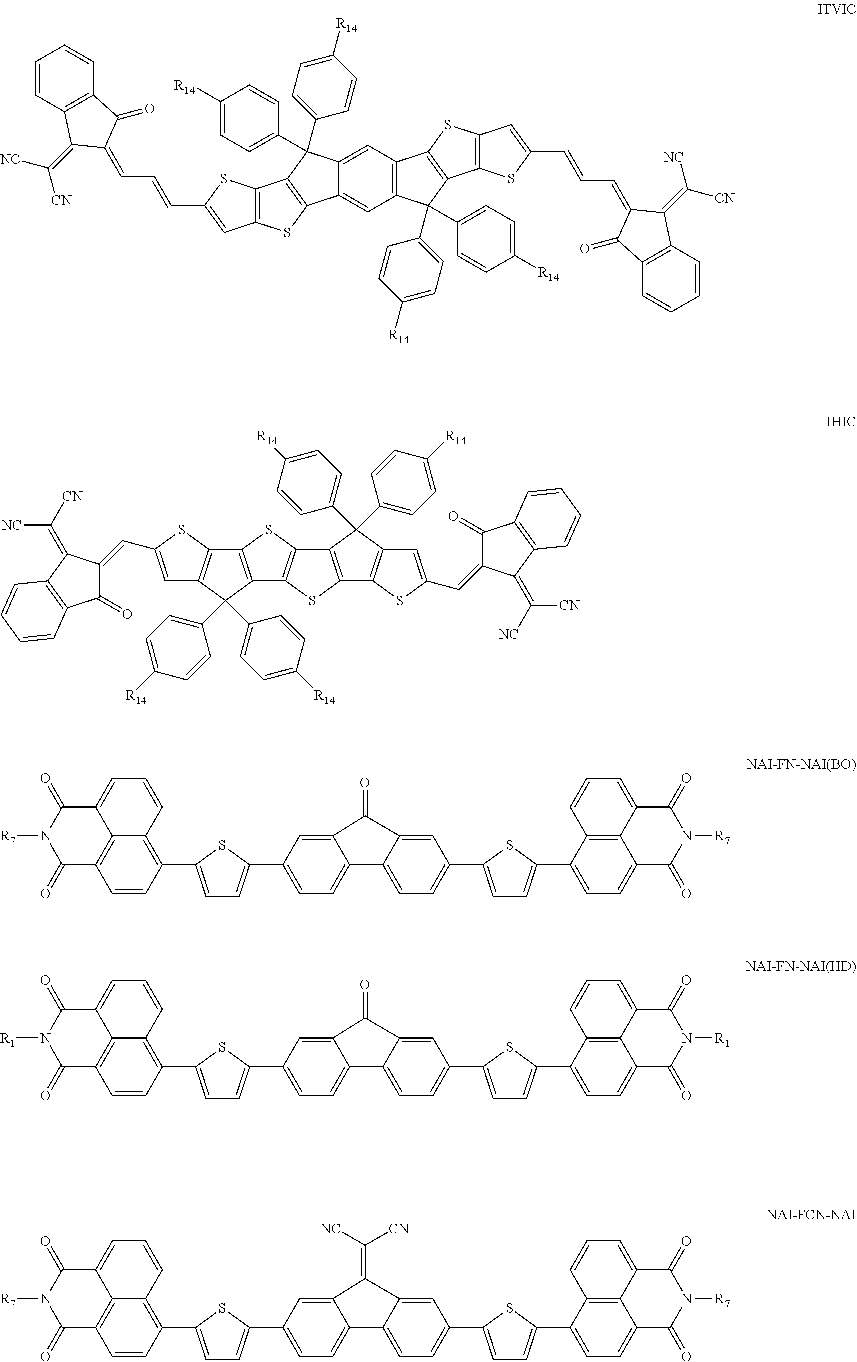

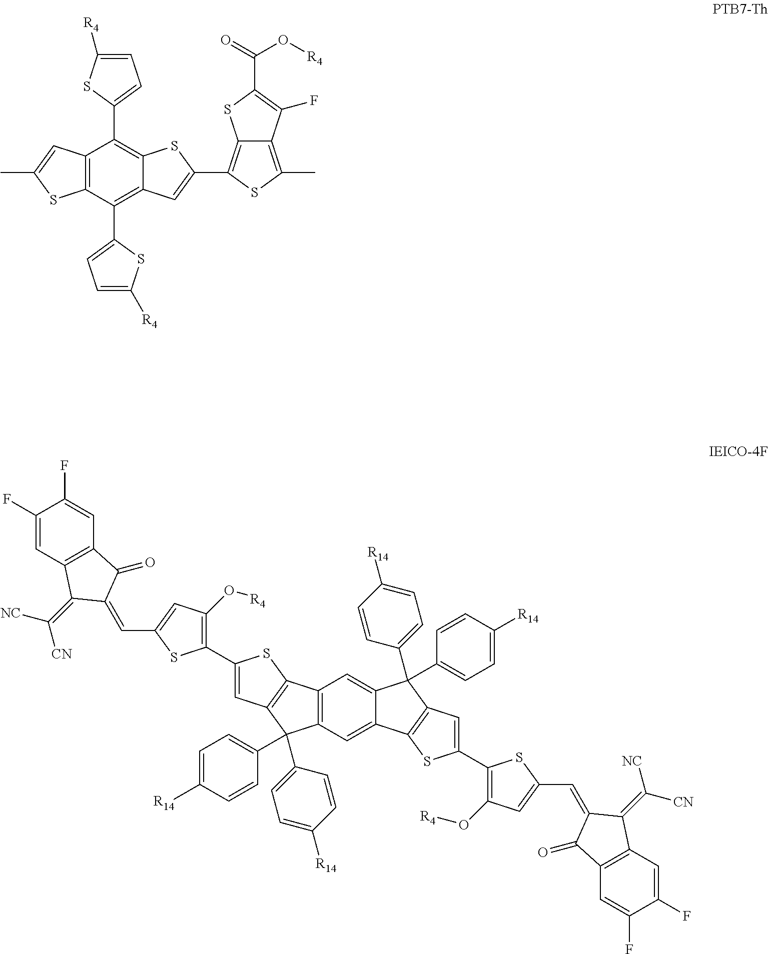

Clearly there exists a need for a more efficient way to identify, design and if necessary to synthesize organic acceptor and organic donors for use in these types of solar cells. We have two distinct but related goals in our innovative design: first, selecting materials for cells within each layer that are complementary to cells in other layers with respect to absorbance and second, configuring components (through use of antireflective layers, adjusting dielectric thicknesses, adjusting the donor/acceptor ratio in active layer, etc.) such that majority of visible spectrum is transmitted by each cell. It has been proven that an AI-guided autonomous material and device acceleration platform can optimize the performance of solar cells purely from absorption measurements. This approach has the potential to reduce the optimization cycle from many hours to a few minutes and create a fully functional organic solar cell. The focus of AI-assisted research in this area has been on improving efficiency. Our innovation, on the other hand, will use AI to optimize the transmissivity of solar cells (and make their absorbance wavelengths complementary to each other) even if it comes at the expense of efficiency because the 3D nature of the construction can improve efficiency for the entire panel.

As noted above currently the process of developing OPV cells have been largely “discovery according to experience-based screening process,” which is inefficient especially when searching for multiple complementary OPV cells to create a 3D structure. As illustrated in some aspects of the instant invention, AI, in general, and GNN/GenAI, in particular, can speed up the discovery of high-performance photoactive materials, electrodes, and other components for creation of organic solar cells with the desired absorption and transmission characteristics. Tens of thousands of organic material combinations have already been created by chemists and material scientists. We can use all this existing information to fine-tune pre-trained models for our specific application. GNN will provide structural information and relationship understanding from spectral-characteristics graph data to allow the GenAI perform nuanced reasoning and find desired materials by having a semantic multimodal understanding of the molecules in the donor and acceptor material. Our innovation will take advantage of pre-trained GenAI, using existing open-source foundation models such as Llama and GPT-NeoX, to find material compositions for complete cells that are complementary to each other in their spectral characteristics, but will allow the visible light to transmit through them even when several of them are stacked on top of each other to create a 3D OPV.

Some aspects of the invention include using AI in a process of aligning an existing foundation model (or other machine learning models) to the specific dataset of existing materials needed to create fully functional organic solar cells with desired characteristics. This process doesn't require the huge investment in time and resources as the original model but can still inject new information into the model. The recommendations from the fine-tuned model are validated in the lab and if it is found that the produced cell is not as expected, more data will be added, and fine-tuning will continue until the desired accuracy is achieved.

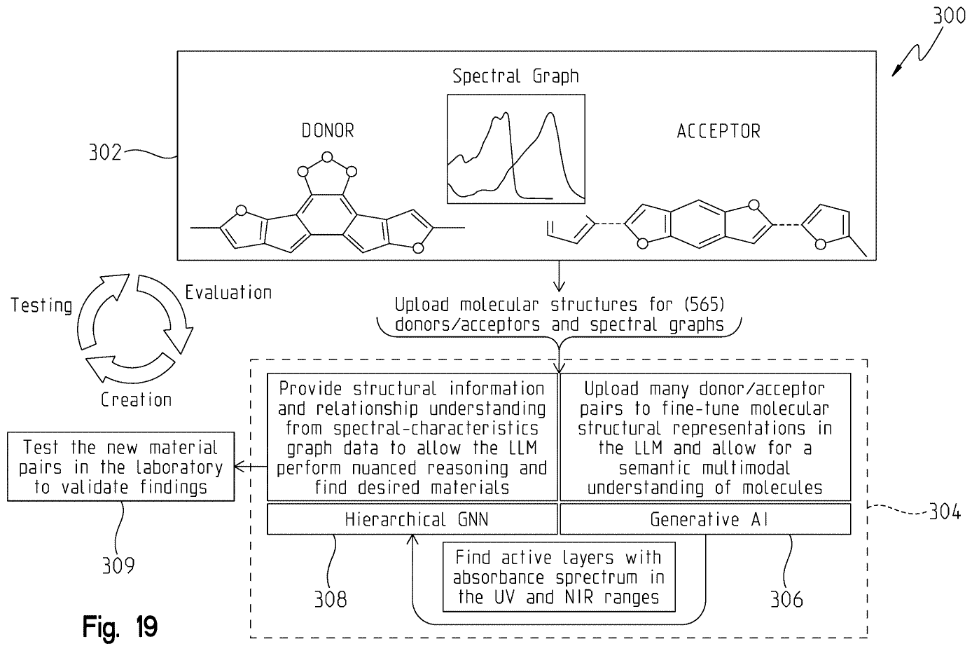

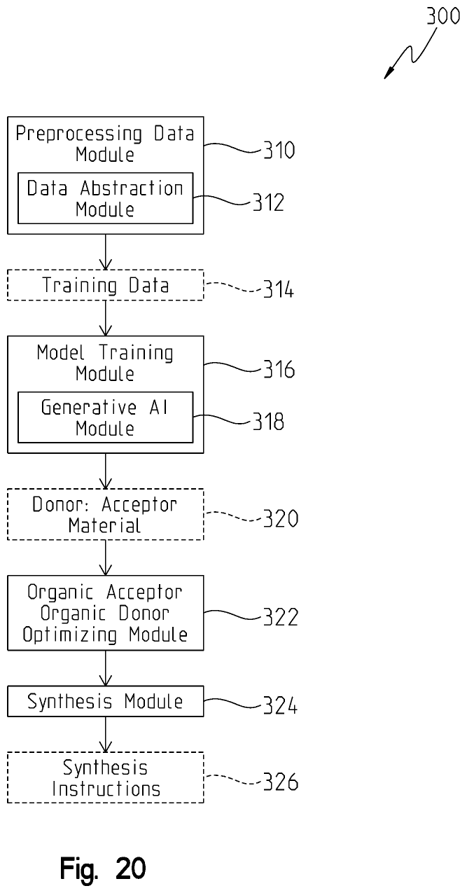

Currently there are thousands of donor-acceptor pairs that are published in the literature for building OPV cells. Instead of relying purely on experimental approaches, we will utilize Graph Neural Network (GNN) and Generative AI (GenAI) to determine the most desired characteristics among the millions of combinations of these existing materials. Furthermore, we will use GenAI to identify new molecular structures of polymers for active materials with highest transmissivity and efficiency. For instance, the absorption region for most donor materials is mainly located in the visible light band. We will use GNN/GenAI to create more appropriate donors and/or reduce the content of polymer donors in the active layer to significantly improve the transmissivity of OPV cells. The diagrams in FIG. 19 and FIG. 20 illustrate our approach which consists of Data Preprocessing by collecting molecular strings, textual descriptions, and spectral data and then extracting molecular graph features and computing spectral features from absorbance spectra.

We will then perform Model Training by training a multimodal model that integrates molecular structure (GNN embeddings) and textual descriptions (LLM embeddings). Next is Evaluation, which includes assessing the model's performance in predicting desired outcomes and validating whether the spectral features improve performance. Finally, we perform Optimization by conducting hyperparameter tuning and iterate these steps to achieve the desired outcomes.

Referring now to FIG. 19, an exemplary computer implemented system 300 suitable to identify, design and optimize organic acceptors and organic donors for use in the fabrication of agrivoltaics. Data 302 for training a machine to identity, design and optimize organic materials may include spectral graphs, texts and/or chemical structures, using a preprocessing data module. Preprocessing data modules can include for example Graph neural networks (GNN) including for example (Hierarchical GNN) 308 can be used to extract data for inputs such as graphs and/or chemical structures. Extracted data can be formatted for use by Large Language Models (LLM) such as Generative AI 306. Available text data and extracted data can be used to train LLM such as Generative AI. The training step may use Large Language Model embeddings and GNN embedding or H-GNN embedding to train a multimodal model, wherein the multimodal models integrates GNN embedding or H-GNN embeddings and LLM embeddings. Training prompts and optimization prompts for multimodal training of a Generative Artificial Intelligence model to identify donor:acceptor material for use as the active layer in an organic photovoltaic cell. The machine-based process may include identifying and/or designing organic acceptor and organic donors that absorb electromagnetic energy in at least one or more ranges selected from the group consisting of: 100 nm to 400 nm, 700 nm to 1100 nm, and 1100 nm to 2500 nm, and also transmits at least 45% of the energy in the spectral region of 400 to 700 nanometers. Further prompts for training the Generative AI includes optimizing Light Utilization Efficiency (LUE) and Average Visible Transmittance (AVT). Target LUE values are greater than or equal to 4.5%; target AVT values are in the range of 45% or more. Once trained Generative AI can be used to identify active layers and/or components for use in active layers such as organic acceptor and organic donors with absorbance and transmittance data suitable for use in agrivoltaics.

Still referring to FIG. 19, outputs 309 from one or more rounds of identification, design and optimization can be evaluate either in the laboratory or in silico, to determine if the materials the physio-chemical properties of the materials to determine if they are suitable for use in agrivoltaics. Data generated by these evaluations, including spectral graph, chemical structure, text, absorbance in certain portions of the spectrum and transmittance in for example the region of the spectra from 400 to 700 nanometers can processed and used to further train the machine and/or to optimize a new generation of materials. The virtual cycle 312 of testing, creating and evaluating materials using this system 300 can be executed one or more time to identify for example organic acceptors organic donors for use in the fabrication of agrivoltaics.

Referring now to FIG. 20, a block diagram of one aspect of the invention includes an apparatus for synthesizing organic photovoltaic cells. The apparatus may include a computer system that includes a Preprocessing Data Module 310, wherein the Preprocessing Data Module 310 and an optional Data Abstraction Module 312, produces training data 314. Preprocessing Date Module 310 and optional Data Abstraction Module 312 may employ a Graph Neural Network (GNN) and or a Hierarchical Graph Neural Network (Hierarchical GNN). These GNN provide structural information and relationship understanding from chemical structure and or spectral-characteristic graphical data for use in training a machine.

Training Data 314 is suitable for machine training or material optimization and is communicated to Model Training Module 316. Model Training Module 316, is used to train Generative Artificial Intelligence Model 318 to identify, design and/or optimize donor:acceptor material as the active layer in an organic photovoltaic cell. In some aspects of the invention the photovoltaic exhibits absorbance and transmittance properties that render it suitable for use in agrivoltaics. In agrivoltaics the desired active layer primarily absorbs electromagnetic energy in at least one or more ranges selected from the group consisting of: 100 nm to 400 nm, 700 nm to 1100 nm, and 1100 nm to 2500 nm and transmits for example 45% or more of the energy in the region of the spectrum between about 400 nm and about 700 nm. Still other prompts for training and criteria for identification and optimization of organic acceptors organic donors include identifying and/or optimizing compounds that possess high Light Utilization Efficiency (LUE) and high visible transmittance (AVT). Desired LUE values are greater than or equal to 4.5%; desired the AVT values are equal to or greater than 45%.

Once trained, Generative AI Module 318 outputs information 320 on organic acceptors and organic donors 320 suitable for use in agrivoltaics. Outputs 320 are communicated to an Organic Acceptor Organic Donor Optimizing Module 322. In comforting with the training provided to the Generative AI the organic acceptor organic donor module optimizes these compounds for use in the fabrication of agrivoltaics. Once optimized the output of module 324 may be combined with training data or further train the Generative AI module. Data from Module 322 may be communicated to a Synthesis Module 324.

Synthesis module 324, may interface with autonomous of semiautonomous synthesizer such as a printer. In some aspects of the invention synthesis module 324, may formulate and communicate instructions 326 including protocols and/or schema for the synthesis of agrivoltaics or organic molecules suitable for use in the fabrication of agrivoltaics.

The invention described herein differs from Tandem Solar Cells (TSCs) in several aspects. TSCs monolithically connect two solar cells to broaden overall absorption spectrum and thus utilize the photon energy more efficiently. First, the design of the present disclosure is not limited to two cells. As we have already discussed, our first 3D OPV prototype has four layers of OPV panels with different cells, and we can increase that number with more complementary cells. Second, we are overlaying complete layers of panels on top of each other not just cells, and thus the name 3D OPV. Special attention will be paid to series and parallel connections of these layers to minimize mismatched voltages and amperages, which are much more difficult to manage in tandem cells. Third, the focus of TSC is only on increasing efficiency whereas we pay special attention to transmissivity as well for agrivoltaics applications. Our 3D OPV system contains donor/acceptor pairs that function in complementary spectral regions that avoid the visible range. Fourth, we use different patterns of printing cells as a way of increasing light diffusion to lower layers. With use of 3D printing technology, we will have lots of freedom on how the panels are laid out on each layer. Fifth, we use twin-wall polycarbonate sheets to act as a substrate and heat sink for cooling middle layers.

To summarize, this invention addresses critical issues in energy and food production by creating semi-transparent 3D organic solar panels for energy-producing agricultural farms. The flexible design and light-weight nature of our proposed panels will reduce the cost of installation and supporting structures. For the organic semiconductor active layer in our own research, we will initially use PM6 and L8-BO materials with a reported 18% solar cell efficiency. We will then use Artificial Intelligence to explore the full range of possible combinations for complementary cells by fine-tuning a GenAI foundation model using the existing donor:acceptor materials and various other components needed for a complete cell. Also, our 3D OPV panels will perform well under low-light or diffuse-light conditions, such as in cloudy weather, and the 3D cells with indium tin oxide (ITO) electrodes will not block light with a wavelength from 400 nm to 700 nm, which is used for photosynthesis by crops and vegetables. Thus, our unique transparent 3D OPV panels will minimally impact the growth of crops and can even improve their quality by absorbing UV light, as excessive UV exposure undermines the biological activity of the plants. Furthermore, thermal insulation and the cooling effect of using twin-wall polycarbonate substrates will result in a longer lifespan of the designed 3D organic panels.

An illustrative apparatus for computational materials discovery in OPVs may comprise: a preprocessing module that canonicalizes molecular strings, constructs molecular graphs with atom/bond features, normalizes spectra, and tokenizes relevant text; a candidate reduction module that reduces a candidate space before graph neural network processing; an embedding module with a GNN and an LLM; a fusion module creating multimodal embeddings; an optimization module that evaluates multi-objective objectives; a selector that outputs donor-acceptor pairs; and a synthesis interface that generates constrained, fabrication-ready instructions. Optional components provide uncertainty estimation, Pareto analysis, explainability, provenance/versioning, safety filters, and closed-loop retraining with new measurements. Note that Pareto analysis (i.e., multi-objective optimization) refers to the set of non-dominated solutions in the LUE-AVT objective space; a candidate is Pareto-optimal if no other candidate improves one objective without worsening the other.

### 1. Training Data Ingestion and Preprocessing

In some aspects, the illustrative system first constructs a training corpus from:
Canonicalized molecular strings and/or graph representations of each candidate donor and acceptor.
Spectral response data associated with those molecules or thin-film combinations (absorption peaks, bandgaps, external quantum efficiency curves).
Free text: publications, patents, lab notebooks, internal reports, technician notes, and all other publicly available relevant sources.

A preprocessing module normalizes each modality. Note that the data abstraction module normalizes schema, units, and provenance across molecular strings/graphs, spectra, and text and exposes a typed API to the model-training module.

### 1.1 Molecular Graphs/Molecular Strings

Each donor and acceptor may be converted into a graph where nodes correspond to atoms and edges correspond to bonds, plus optional features such as aromaticity, substituent class, and known stability constraints (e.g. hydrolytic sensitivity). For some variants, a hierarchical GNN (H-GNN) is used to treat functional groups or substructures as higher-level nodes.

### 1.2 Spectral Data

Spectral curves and device-level optical parameters can be resampled into a consistent representation, e.g. a fixed-length vector capturing absorbance across UV, visible, and NIR bands, predicted AVT under standard illumination, and predicted LUE.

### 1.3 Text Data

Reported synthesis procedures, solvent systems, anneal temperatures, hole/electron mobility stats, morphological notes (phase separation quality, crystallinity), degradation issues, encapsulation notes, etc. may be treated as text passages.

The LLM tokenizer encodes this text and produces dense embeddings. Because this model is trained or instruction-tuned on OPV-relevant corpora, it recognizes that “high haze in visible band” is negative for transparent greenhouse glazing, or that “annealed at 110° C. for 2 minutes on PET without curling” suggests good manufacturability.

### 1.4 Alignment/Pairing

For each donor-acceptor pair, the system associates:
donor graph embedding,
acceptor graph embedding,
experimental/simulated spectral signature of the pair, and
summarized text embeddings describing that pair's synthesis and performance notes.

### 2. Embedding and Multimodal Fusion

The illustrative system may include:
a GNN (or H-GNN) that produces embeddings from the molecular graph and spectral attributes,
an LLM that produces embeddings from free text, and
a fusion module that combines them into a joint multimodal embedding.

The fusion module can be a learned projection that maps the GNN vector and the LLM vector into a shared latent space, then concatenates or attentively pools them. The resulting multimodal embedding represents in a single vector:
structure,
optical behavior,
manufacturability concerns, and
prior practical synthesis knowledge.

It is important to follow such a process in some aspects because a pure GNN might assign a favorable score to a molecule that is theoretically efficient but impossible to synthesize safely at scale, or a pure LLM might score favorably something often reported in literature even if its visible transmittance is too low for transparent applications. The fused embedding encodes both.

In some illustrative embodiments, the embedding and fusion process is selectively invoked according to a routing module. The routing module determines whether a candidate or candidate pair should be evaluated using low-cost molecular-language embeddings, graph neural network embeddings, hierarchical graph embeddings, geometry-aware graph neural network embeddings, physics-aware simulation, or combinations thereof. The routing module may use candidate novelty, predicted performance, uncertainty, diversity score, compliance status, spectral fit, or synthesis feasibility as routing criteria. This permits the system to apply computationally expensive graph-based or physics-aware analysis only to candidates for which such analysis is expected to provide additional value.

### 3. Objective-Driven Optimization

The fused embedding for each donor-acceptor pair can be evaluated by an optimization module. The optimization module computes an objective score subject to multi-objective constraints, such as:
Increase or maximize luminance utilization efficiency (LUE).
Maintain or increase average visible transmittance (AVT) above a threshold.
Bias absorption to UV and/or NIR ranges (for example below 400 nm and above 700 nm) to avoid blocking visible light.
Respect process constraints like maximum anneal temperature compatible with flexible polymer substrates.

The optimization module can be implemented as:
a Bayesian optimizer over the fused embedding space,
an evolutionary algorithm that mutates embeddings/pairs and searches for Pareto-optimal trade-offs, or
a gradient-driven scorer trained to regress predicted performance metrics and rank candidates.

In some illustrative embodiments, the optimizer explicitly computes a Pareto front between LUE and AVT. A pair lying on the Pareto front is one that cannot improve AVT without hurting LUE, or vice versa. Candidates on or near the Pareto front are considered high-value outputs with the final selection being the one chosen for implementation.

In some illustrative embodiments, the optimization module operates on a reduced candidate set produced by the staged candidate down-selection process. The reduced candidate set may be generated by applying one or more sequential filters comprising: molecular validity checking, synthetic accessibility scoring, spectral compatibility scoring, average visible transmittance thresholding, predicted LUE thresholding, solvent and process compatibility filtering, preliminary molecular-language-model ranking, clustering-based diversity selection, and uncertainty-based exploration selection. The reduced candidate set is then provided to the GNN, H-GNN, fusion module, or physics-aware scoring module for higher-fidelity evaluation.

The optimization module may maintain an exploration-exploitation balance by selecting a first portion of candidates based on predicted objective performance, a second portion based on structural or spectral diversity, and a third portion based on uncertainty or out-of-distribution detection. The relative portions may be fixed, adaptive, or learned based on feedback from experimental validation.

### 4. Selection of Donor-Acceptor Pairs and Synthesis

After scoring, the selector module chooses one or more donor-acceptor pairs from a predefined database, generated library, enumerated candidate set, active-learning candidate set, or combinations thereof. The selection can also incorporate uncertainty and production feasibility: pairs with high predicted score and low model uncertainty are sent directly to synthesis; pairs with high uncertainty but potentially extreme upside are flagged for targeted experimentation, to improve the model.

Once a candidate pair is selected, the system generates synthesis instructions for candidate molecular structures. A synthesis interface module uses the LLM to draft a step-by-step procedure. This includes:
Required precursors and their purities.
Solvents and solvent ratios.
Dissolution temperatures.
Coating or deposition method (e.g. spin coat, blade coat, slot-die).
Annealing or drying temperature/time.
Layer thickness targets.
Any post-treatment such as mild thermal anneal or solvent vapor anneal to tune morphology.

Because the LLM is conditioned on the fused multimodal embedding (not generic text alone), the generated procedure is tied to what the optimizer actually approved. This closes the loop: the system does not just say “this donor-acceptor pair has promise,” it says “here is how to make a thin film with it consistent with the optical/AVT constraints.”

In some illustrative embodiments, the synthesis output also includes constraints or warnings such as “avoid chlorinated solvent above X° C. due to breakdown,” “do not exceed Y nm thickness or visible haze increases significantly,” or “constrain selection by compliance filters that exclude specified toxic components and hazardous solvents.” At one or more stages, the system may evaluate and address the process, the materials and synthesis pathway.

### 5. Closed-Loop Experimental Feedback

After fabrication and measurement, new data are fed back:
measured AVT,
measured LUE or related performance metrics,
observed thickness uniformity,
presence/absence of morphological defects like pinholes or crystallization, and
updated actual spectra.

This new information may be appended to the training corpus. The GNN retrains (or fine-tunes) on the updated structure/performance relationship. The LLM retrains or instruction-tunes on validated synthesis steps and outcomes. The optimizer is then rerun with improved predictive accuracy.

This feedback loop is important for at least two reasons:
1. It moves the system from “static recommender” to “active learner.”
2. It documents provenance and versioning: which model generated the successful recipe, under what data assumptions, and with what confidence.

In some illustrative embodiments, the system includes a validation module configured to validate predicted donor-acceptor pairs before synthesis, after synthesis, or both. The validation module may compare predicted AVT, LUE, spectral absorption, bandgap, morphology, stability, solubility, or manufacturability values against experimental measurements, density functional theory calculations, molecular dynamics simulations, optical simulations, historical OPV datasets, or known benchmark materials. The validation module may compute calibration metrics, confidence intervals, prediction residuals, conformal prediction bounds, or out-of-distribution indicators.

In some illustrative embodiments, validation results are used to update one or more of the molecular-language model, graph neural network, fusion module, optimizer, uncertainty estimator, compliance filter, or synthesis interface. The system may prioritize subsequent experiments based on expected improvement, uncertainty reduction, novelty, diversity, or expected information gain.

### 6. Compliance and Filtering

In some illustrative embodiments, before instructions go out, a filter module evaluates:
toxicity,
regulatory limitations on solvents or precursors, and
sustainability flags such as high-cost rare precursors.

Candidates that violate safety or compliance constraints can be downgraded or blocked. This is useful both from an ethical standpoint and to ensure that the new materials have industrial utility. The system is not merely guessing molecules; it is proposing molecules plus workable synthesis that satisfy optical/electrical targets while staying inside practical synthesis constraints.

### 7. Apparatus: Modules and Interactions

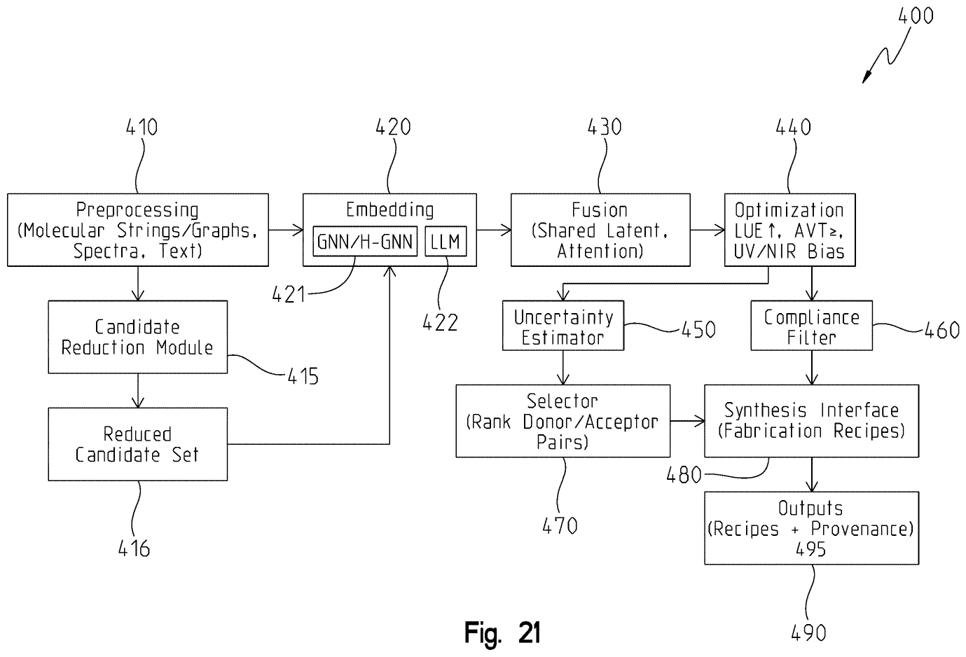

As shown in FIG. 21, apparatus 400 includes a preprocessing module 410, a candidate reduction module 415, and an embedding module 420 that comprises a GNN/H-GNN submodule 421 and an LLM submodule 422. Embeddings are provided to a fusion module 430, which outputs a multimodal representation to an optimization module 440. Optional components include an uncertainty estimator 450 and a compliance filter 460. A selector 470 chooses donor-acceptor candidates for a synthesis interface 480, which emits fabrication recipes that are stored as outputs 490 with associated provenance 495.

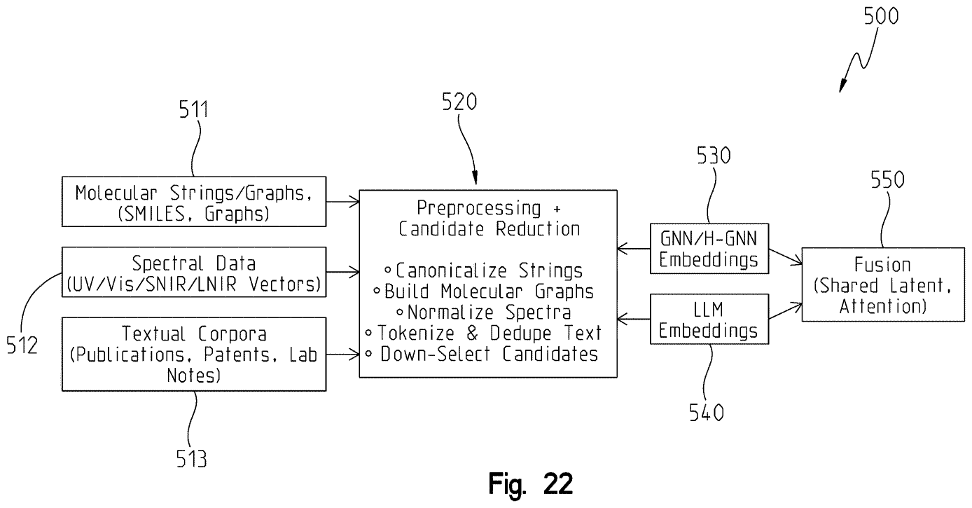

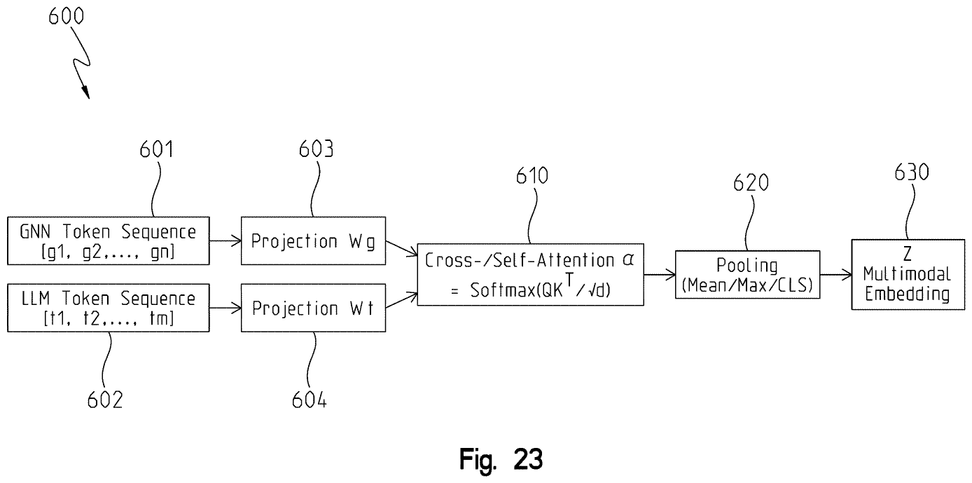

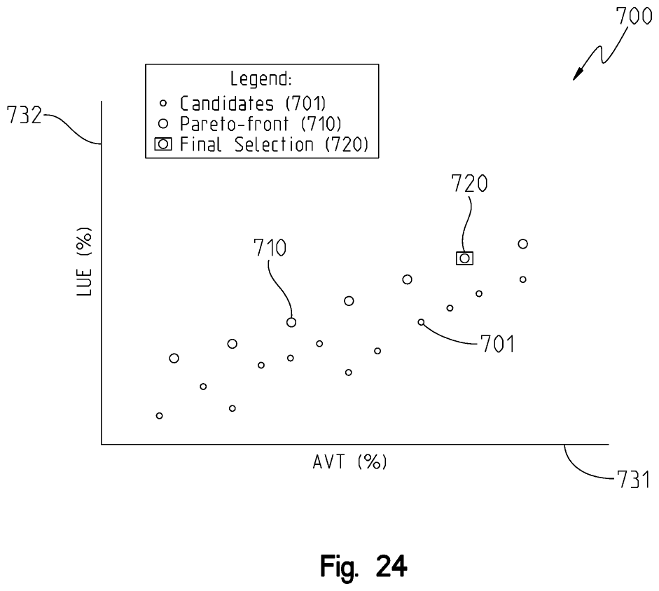

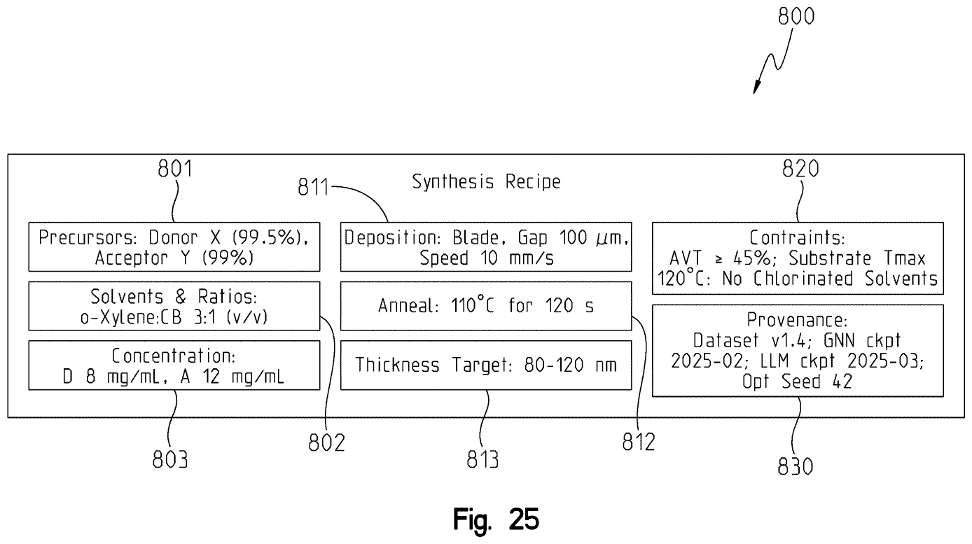

A corresponding illustrative method is visualized in FIGS. 22-25, which correspond to preprocessing pipeline 500, multimodal fusion stack 600, multi-objective optimization scene 700, and synthesis interface 800, respectively, all operating over the apparatus of FIG. 21. In the illustrative embodiments below, each apparatus element may have an associated operational method step. Furthermore, as shown in FIG. 21, modules 410-490 correspond to the related apparatus and provide contextual support for the illustrative method. In FIG. 22, preprocessing pipeline 500 supports multimodal data preparation and candidate reduction; FIG. 23, fusion stack 600, supports the multimodal and LLM+GNN embedding language; FIG. 24, optimization scene 700, supports multi-objective optimization and Pareto-based selection; and FIG. 25, synthesis interface 800 supports synthesis instruction generation, constraints, provenance, and output reporting. Finally, FIGS. 19 and 20 show a data flow and block diagram of one possible computer-implemented system that can be used to identify suitable transparent OPV materials.

### 7.1 Preprocessing Module

The preprocessing module 410 canonicalizes molecular strings by: a) constructing molecular graphs with atom/bond features (e.g., aromaticity, ring membership, functional-group indicators); b) normalizing spectral vectors across UV/visible/NIR; c) tokenizing textual corpora (publications, patents, lab notes); and d) deduplicating and attaching metadata. Candidate reduction module 415 reduces a candidate space of candidate donor materials, candidate acceptor materials, or donor-acceptor material compositions before graph neural network processing. The candidate reduction module 415 may receive normalized data from preprocessing module 410 and may provide a reduced candidate set 416 to embedding module 420. In some embodiments, candidate reduction module 415 may be implemented as a separate module, as shown in FIG. 21, or integrated into preprocessing module 410, preprocessing pipeline 500, or a staged evaluation engine.

FIG. 22 details pipeline 500: molecular strings/graphs 511, spectral tensors 512, and textual corpora 513 enter preprocessing+candidate reduction steps in 520, which canonicalizes molecular strings, builds molecular graphs, normalizes spectra, tokenizes text, deduplicates records, and down-selects candidates. The resulting datasets feed the GNN/H-GNN submodule 421 and LLM submodule 422 of FIG. 21.

### 7.2 Embedding Module

The embedding module 420 includes GNN/H-GNN submodule 421 and LLM submodule 422. The GNN/H-GNN submodule 421 generates structure/spectral embeddings from molecular graphs and spectral attributes.

LLM 422 generates text embeddings and performs conditioned generation.

The embedding outputs from 421/422 and 530/540 are consumed by fusion modules 430 and 550, respectively, as indicated in FIGS. 21 and 22.

### 7.3 Fusion Module

The fusion module 430 projects GNN and LLM embeddings into a shared latent space and applies attention-based fusion to form a multimodal embedding per candidate or donor-acceptor pair. As shown in FIG. 23, fusion stack 600 projects GNN tokens 601 and LLM tokens 602 via linear projections 603 and 604 into a shared latent, applies cross-/self-attention 610, and pools 620 to produce multimodal embedding 630, which is provided to the optimization module 440 of FIG. 21.

### 7.4 Optimization Module

The optimization module 440 evaluates the multimodal embeddings against objectives including increasing LUE, maintaining or increasing AVT, and biasing absorption toward UV and/or NIR while suppressing visible-band absorbance. FIG. 24 depicts the optimization scene 700 where candidates 701 are scored on AVT and LUE axes 731 and 732. Modeled frontier 710 indicates Pareto-efficient points, which are passed to selector 470 (see FIG. 21) to make the final selection 720 (i.e., the one chosen for implementation). Note that other factors besides maximum AVT and LUE (e.g., synthesis viability) should be considered when making this final selection.

### 7.5 Selector

The selector 470 chooses donor-acceptor pairs from a predefined database, generated library, enumerated candidate set, active-learning candidate set, or combinations thereof based on optimization outputs, synthesis viability, uncertainty, compliance signals, novelty, diversity, or predicted improvement.

### 7.6 Synthesis Interface

The synthesis interface 480 conditions the LLM on the optimized multimodal embeddings and emits stepwise fabrication instructions: precursor identity/purity; solvent systems/ratios; deposition parameters (spin/blade/slot-die); anneal temperatures/times; layer-thickness targets to preserve AVT. As illustrated in FIG. 25, synthesis panel 800 converts selected candidates into stepwise recipes comprising fields 801, 802, 803 and 811, 812, 813 (precursors, solvents/ratios, concentrations, deposition parameters, anneal conditions, thickness targets). Constraint block 820 enforces AVT thresholds and process ceilings; provenance block 830 logs dataset/model versions and optimizer parameters (captured as 495 in FIG. 21).

### 7.7 Provenance and Compliance

Outputs module 490 logs dataset/model versions and optimizer parameters for each recipe; applies safety constraints (e.g., prohibitive solvent classes and toxic components, temperature ceilings, etc.).

In some illustrative embodiments, the apparatus further includes an explainability module configured to generate an explanation package for each selected donor-acceptor pair. The explanation package may include one or more of: molecular substructures contributing to predicted performance, atom-level or bond-level attribution scores, graph attention weights, nearest-neighbor candidates in embedding space, spectral regions contributing to predicted AVT or LUE, text passages supporting synthesis feasibility, compliance factors, uncertainty scores, provenance identifiers, and graph paths linking candidate structure, predicted properties, optimization objectives, and synthesis instructions.

The explainability module may classify outputs as verified, predicted, uncertain, or requiring experimental validation. The explanation package may be stored with the generated synthesis recipe so that a chemist, engineer, automated synthesis system, or reviewer can determine why a candidate was selected and what evidence supports the selection.

### 8. Method of Operation

The illustrative method is shown in FIGS. 22-25: inputs 511, 512, 513 undergo steps in 520 (FIG. 22) to produce embeddings in 421/422 that are fused (FIG. 23, 600) into embedding 630; optimization (FIG. 24, 700) selects near-front candidates 720 under LUE/AVT objectives (731/732); the synthesis interface (FIG. 25, 800) generates recipe fields 801, 802, 803 and 811, 812, 813 under constraints 820 and records provenance 830 for outputs 490 (FIG. 21). In other words, the illustrative method of operation:
1. Receives and preprocesses molecular graphs/strings, spectra and textual corpora;
2. Reduces the candidate space using preliminary screening operations, including molecular validity filtering, synthetic accessibility scoring, spectral compatibility scoring, molecular-language-model embedding, clustering, diversity selection, uncertainty-based selection, or combinations thereof;
3. Generates GNN/H-GNN structure/spectral embeddings and LLM text embeddings;
4. Fuses into multimodal embeddings via attention pooling;
5. Optimizes to increase LUE with maintained or increased AVT;
6. Biases absorption to UV, Short-wave NIR (SNIR), and Long-wave NIR (LNIR) windows (i.e., 100-400 nm, 700-1100 nm, and 1100-2500 nm, respectively);
7. Selects donor-acceptor pairs; computes Pareto proximity and uncertainty (optional); and
8. Generates synthesis instructions conditioned on embeddings and constraints, includes provenance, applies compliance filters, and iterates with experimental feedback.

### 9. Examples and Implementation Notes

GNN features: atom types, valence, aromatic flags, ring membership; edges distinguish single/double/π-conjugation.
Spectra: UV 100-400 nm, visible 400-700 nm, SNIR 700-1100, and LNIR 1100-2500 nm with standardized illuminant weighting.
Optimization: scalarization with adaptive weights; hypervolume (Pareto) improvement; evolutionary search in embedding space; gradient-based ranking if differentiable.
Synthesis outputs: solution concentrations; solvent identities/ratios; deposition parameters; anneal windows; thickness targets; allowed substitutions.

In the below claims, each apparatus element has an associated operational method. Furthermore, as shown in FIG. 21, modules 410-490 correspond to the claimed apparatus and provide contextual support for the claimed method (the method runs “over the apparatus”). In FIG. 22, the preprocessing pipeline 500 supports apparatus claims and method claims. In FIG. 23, the fusion stack 600 grounds the multimodal and LLM+GNN embedding language in apparatus claims and method claims. In FIG. 24, the optimization scene 700 supports apparatus claims and method claims. In FIG. 25, synthesis interface 800 supports apparatus claims and method claims. Finally, FIGS. 19 and 20 show a data flow and block diagram of one possible computer implemented system that can be used to identify suitable transparent OPV materials.

Although the invention has been described in detail with reference to certain preferred embodiments, variations and modifications exist within the spirit and scope of the invention as described and defined in the following claims.

What is claimed is:

1. An apparatus for identifying an organic photovoltaic film material composition comprising at least one donor material and at least one acceptor material, the apparatus comprising:
(a) a preprocessing module configured to receive material data associated with candidate donor materials and candidate acceptor materials, the material data including molecular graphs or molecular strings, spectral data, and textual data, wherein the preprocessing module is further configured to normalize the material data;
(b) a candidate reduction module configured to reduce a candidate space of candidate donor materials, candidate acceptor materials, or donor-acceptor material compositions before graph neural network processing, thereby producing a reduced candidate set;
(c) an embedding module configured to evaluate the reduced candidate set, the embedding module comprising a graph neural network configured to generate first embeddings from molecular graphs or molecular strings and spectral data for at least a subset of candidates in the reduced candidate set, and a large language model configured to generate second embeddings from textual data;
(d) a fusion module configured to form multimodal embeddings by combining the first embeddings and the second embeddings;
(e) an optimization module configured to evaluate the multimodal embeddings with respect to a multi-objective function comprising at least increasing luminance utilization efficiency (LUE) and maintaining or increasing average visible transmittance (AVT);
(f) a selector configured to select at least one donor-acceptor material composition based on outputs of the optimization module; and
(g) a synthesis interface configured to generate synthesis instructions for fabricating a thin film using the selected donor-acceptor material composition.

2. The apparatus of claim 1, wherein the candidate reduction module reduces the candidate space using one or more preliminary screening operations comprising molecular validity filtering, synthetic accessibility scoring, spectral compatibility scoring, toxicity filtering, compliance filtering, molecular-language-model embedding, clustering, diversity selection, uncertainty-based selection, approximate property prediction, or combinations thereof.

3. The apparatus of claim 2, wherein the molecular-language-model embedding is generated from one or more tokenized molecular representations, molecular descriptors, molecular fragments, OPV-specific text, synthesis-related text, spectral descriptions, or combinations thereof.

4. The apparatus of claim 1, wherein the candidate reduction module selects the reduced candidate set to include candidates selected based on predicted objective performance, candidates selected based on structural or spectral diversity, and candidates selected based on uncertainty, novelty, out-of-distribution detection, or expected information gain.

5. The apparatus of claim 1, further comprising a routing module or staged evaluation engine configured to route candidates among molecular-language-model screening, graph neural network scoring, hierarchical graph neural network scoring, geometry-aware graph neural network scoring, multimodal fusion, physics-aware simulation, or combinations thereof based on predicted performance, novelty, uncertainty, diversity score, compliance status, spectral fit, synthesis feasibility, or computational cost.

6. The apparatus of claim 1, wherein the embedding module comprises a hierarchical graph neural network configured to generate structure-aware embeddings at both atom and substructure levels and the large language model is a transformer-based language model.

7. The apparatus of claim 1, wherein the fusion module projects the first and second embeddings into a common latent space and computes attention-based fusion.

8. The apparatus of claim 1, wherein the optimization module biases absorption toward ultraviolet and/or near-infrared bands, reduces visible-band absorption, computes a Pareto front between LUE and AVT, and provides a rank ordering of candidates on or proximate to the front.

9. The apparatus of claim 1, further comprising an uncertainty estimator configured to compute confidence measures, calibration values, prediction intervals, or out-of-distribution scores for predicted outcomes and to prioritize candidates for physical validation based on predicted improvement, uncertainty, novelty, diversity, or expected information gain.

10. The apparatus of claim 1, wherein the candidate reduction module, selector, or synthesis interface filters, flags, rejects, penalizes, or modifies candidates or synthesis instructions using compliance criteria that exclude or penalize specified toxic precursors, hazardous solvents, restricted materials, or processing temperature ranges above predetermined limits.

11. A computer-implemented method for identifying an organic photovoltaic film material composition comprising:
(a) preprocessing material data associated with candidate donor materials and candidate acceptor materials, the material data including molecular graphs or molecular strings, spectral data, and textual data;
(b) reducing a candidate space of candidate donor materials, candidate acceptor materials, or donor-acceptor material compositions before graph neural network processing, thereby producing a reduced candidate set;
(c) generating, via a graph neural network, first embeddings from molecular graphs or molecular strings and spectral data for at least a subset of candidates in the reduced candidate set;
(d) generating, via a large language model, second embeddings from textual data;
(e) forming multimodal embeddings by combining the first and second embeddings;
(f) optimizing the multimodal embeddings according to a multi-objective function comprising at least increasing luminance utilization efficiency (LUE) and maintaining or increasing average visible transmittance (AVT);
(g) selecting at least one donor-acceptor material composition based on results of the optimizing; and
(h) generating synthesis instructions for fabricating a thin film using the selected donor-acceptor material composition.

12. The method of claim 11, wherein reducing the candidate space comprises applying one or more preliminary screening operations comprising molecular validity filtering, synthetic accessibility scoring, spectral compatibility scoring, toxicity filtering, compliance filtering, molecular-language-model embedding, clustering, diversity selection, uncertainty-based selection, approximate property prediction, or combinations thereof.

13. The method of claim 12, wherein the molecular-language-model embedding is generated from one or more tokenized molecular representations, molecular descriptors, molecular fragments, OPV-specific text, synthesis-related text, spectral descriptions, or combinations thereof.

14. The method of claim 11, wherein reducing the candidate space comprises selecting a reduced candidate set including candidates selected based on predicted objective performance, candidates selected based on structural or spectral diversity, and candidates selected based on uncertainty, novelty, out-of-distribution detection, or expected information gain.

15. The method of claim 11, further comprising routing candidates among molecular-language-model screening, graph neural network scoring, hierarchical graph neural network scoring, geometry-aware graph neural network scoring, multimodal fusion, physics-aware simulation, or combinations thereof based on predicted performance, novelty, uncertainty, diversity score, compliance status, spectral fit, synthesis feasibility, or computational cost.

16. The method of claim 11, wherein forming the multimodal embeddings comprises projecting the first and second embeddings into a shared latent space and computing attention-based fusion.

17. The method of claim 11, further comprising computing a Pareto front between LUE and AVT and identifying candidates located on or proximate to the Pareto front.

18. The method of claim 11, further comprising computing model uncertainty, calibration values, prediction intervals, or out-of-distribution scores and prioritizing candidates for experimental validation based on uncertainty, predicted improvement, novelty, diversity, or expected information gain.

19. The method of claim 11, wherein selecting outputs a rank-ordered list of donor-acceptor material compositions with associated predicted AVT, predicted LUE, uncertainty score, novelty score, synthesis-feasibility score, compliance status, provenance information, and explanation data comprising at least one of molecular substructure attribution, spectral-region contribution, graph-based attribution, or supporting textual evidence.

20. The method of claim 11, further comprising storing multimodal embeddings, candidate reduction scores, model versions, data versions, validation outcomes, synthesis outcomes, and corresponding experimental measurements for subsequent active-learning iterations.
